(19) United States
(12) Patent Application Publication
(10) Pub. No.: US 2024/0315015 A1
(43) Pub. Date: Sep. 19, 2024

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventor: Masashi ARINO, Yokkaichi Mie (JP)

(73) Assignee: Kioxia Corporation, Tokyo (JP)

(21) Appl. No.: 18/585,606

(22) Filed: Feb. 23, 2024

(30) Foreign Application Priority Data
Mar. 14, 2023 (JP) 2023-039936

(51) Int. Cl. H10B 41/27; H10B 41/10; H10B 43/10; H10B 43/27

(52) U.S. Cl. CPC H10B 41/27; H10B 41/10; H10B 43/10; H10B 43/27

(57) ABSTRACT

A semiconductor memory device includes: a stacked body including conductive layers and insulating layers alternately stacked on top of one another in a vertical direction; a first pillar including a semiconductor layer extending within the stacked body; and a separation layer penetrating through an uppermost one of the conductive layers, or the uppermost conductive layer and an another conductive layer coupled to the uppermost conductive layer in the vertical direction, extending within the stacked body in a first direction that intersects the vertical direction, and separating one or more conductive layers including the uppermost conductive layer in a second direction that intersects the vertical direction and the first direction. The separation layer includes at least a portion extending into the stacked body that is overlapped with the first pillar in the vertical direction, and having a lower end in contact with an upper surface of the first pillar.

### CROSS-REFERENCE TO RELATED APPLICATION

This application is based upon and claims the benefit of priority from Japanese Patent Application No. 2023-039936, filed Mar. 14, 2023, the entire contents of which are incorporated herein by reference.

### FIELD

Embodiments described herein relate generally to a semiconductor memory device and a method for manufacturing the semiconductor memory device.

### BACKGROUND

A semiconductor memory device such as a three-dimensional nonvolatile memory includes a plurality of pillars that penetrate a stacked body in which a plurality of conductive layers are stacked, for example. Each of intersections between the plurality of conductive layers and the pillars functions as a memory cell. To independently control the memory cells belonging to each pillar, one or more conductive layers, including an uppermost conductive layer of the stacked body, are separated by a separation layer.

Since the plurality of pillars are arranged at high density, the separation layer is formed at a position overlapping some of the pillars such that upper ends of the pillars are missing. Then, the characteristics of memory cells belonging to the pillars with a missing portion deteriorate.

### DESCRIPTION OF THE DRAWINGS

FIG. 1 is a cross-sectional view illustrating a schematic configuration example of a semiconductor memory device according to a first embodiment;

FIGS. 2A to 2E are diagrams illustrating one example of the configuration of the semiconductor memory device according to the first embodiment;

FIGS. 3A to 3B are diagrams illustrating one example of the configuration of the semiconductor memory device according to the first embodiment;

FIGS. 4A to 4C are diagrams sequentially illustrating a part of the procedure of a manufacturing method of the semiconductor memory device according to the first embodiment;

FIGS. 5A to 5C are diagrams sequentially illustrating a part of the procedure of the manufacturing method of the semiconductor memory device according to the first embodiment;

FIGS. 6A to 6C are diagrams sequentially illustrating a part of the procedure of the manufacturing method of the semiconductor memory device according to the first embodiment;

FIGS. 7A to 7C are diagrams sequentially illustrating a part of the procedure of the manufacturing method of the semiconductor memory device according to the first embodiment;

FIGS. 8A to 8C are diagrams sequentially illustrating a part of the procedure of the manufacturing method of the semiconductor memory device according to the first embodiment;

FIGS. 9A to 9C are diagrams sequentially illustrating a part of the procedure of the manufacturing method of the semiconductor memory device according to the first embodiment;

FIGS. 10A to 10C are diagrams sequentially illustrating a part of the procedure of the manufacturing method of the semiconductor memory device according to the first embodiment;

FIGS. 11A to 11C are diagrams sequentially illustrating a part of the procedure of the manufacturing method of the semiconductor memory device according to the first embodiment;

FIGS. 12A to 12C are diagrams sequentially illustrating a part of the procedure of the manufacturing method of the semiconductor memory device according to the first embodiment;

FIG. 13 is an XY cross-sectional view at a height position of a selection gate line of a semiconductor memory device according to a comparative example;

FIG. 14 is a cross sectional view along the Y direction illustrating an example of the configuration of a semiconductor memory device according to a modification of the first embodiment;

FIGS. 15A to 15C are cross-sectional views along the Y direction illustrating a part of the procedure of a manufacturing method of the semiconductor memory device according to the modification of the first embodiment;

FIGS. 16A to 16D are diagrams illustrating one example of the configuration of a semiconductor memory device according to a second embodiment;

FIGS. 17A to 17C are diagrams sequentially illustrating a part of the procedure of a manufacturing method of the semiconductor memory device according to the second embodiment;

FIGS. 18A to 18C are diagrams sequentially illustrating a part of the procedure of the manufacturing method of the semiconductor memory device according to the second embodiment;

FIGS. 19A to 19B are diagrams sequentially illustrating a part of the procedure of the manufacturing method of the semiconductor memory device according to the second embodiment;

FIGS. 20A to 20C are diagrams sequentially illustrating a part of the procedure of the manufacturing method of the semiconductor memory device according to the second embodiment;

FIGS. 21A to 21C are diagrams sequentially illustrating a part of the procedure of the manufacturing method of the semiconductor memory device according to the second embodiment;

FIGS. 22A to 22C are cross sectional views along the Y direction illustrating an example of the configuration of a semiconductor memory device according to a modification of the second embodiment;

FIGS. 23A to 23C are diagrams sequentially illustrating a part of the procedure of a manufacturing method of the semiconductor memory device according to the modification of the second embodiment;

FIGS. 24A to 24C are diagrams sequentially illustrating a part of the procedure of the manufacturing method of the semiconductor memory device according to the modification of the second embodiment; and

FIGS. 25A to 25C are diagrams sequentially illustrating a part of the procedure of the manufacturing method of the semiconductor memory device according to the modification of the second embodiment.

### DETAILED DESCRIPTION

Embodiments provide a semiconductor memory device and a method for manufacturing the semiconductor memory device that can improve the characteristics of a memory cell.

In general, according to one embodiment, a semiconductor memory device includes a stacked body including a plurality of conductive layers and a plurality of insulating layers alternately stacked on top of one another in a vertical direction; a first pillar including a semiconductor layer extending within the stacked body in the vertical direction; and a separation layer penetrating through an uppermost one of the conductive layers, or the uppermost conductive layer and an another one of the conductive layers that is coupled to the uppermost conductive layer in the vertical direction, extending within the stacked body in a first direction that intersects the vertical direction, and separating one or more conductive layers including the uppermost conductive layer in a second direction that intersects the vertical direction and the first direction. The separation layer includes at least a portion extending into the stacked body that is overlapped with the first pillar in the vertical direction, and having a lower end in contact with an upper surface of the first pillar.

Embodiments of the present disclosure will be described in detail below with reference to the drawings. The present disclosure is not limited by the embodiments described below. The components in the embodiments described below include those that can be easily imagined by those skilled in the art or those that are substantially the same.

### First Embodiment

Hereinafter, the first embodiment will be described with reference to the drawings.

### Configuration Example of Semiconductor Memory Device

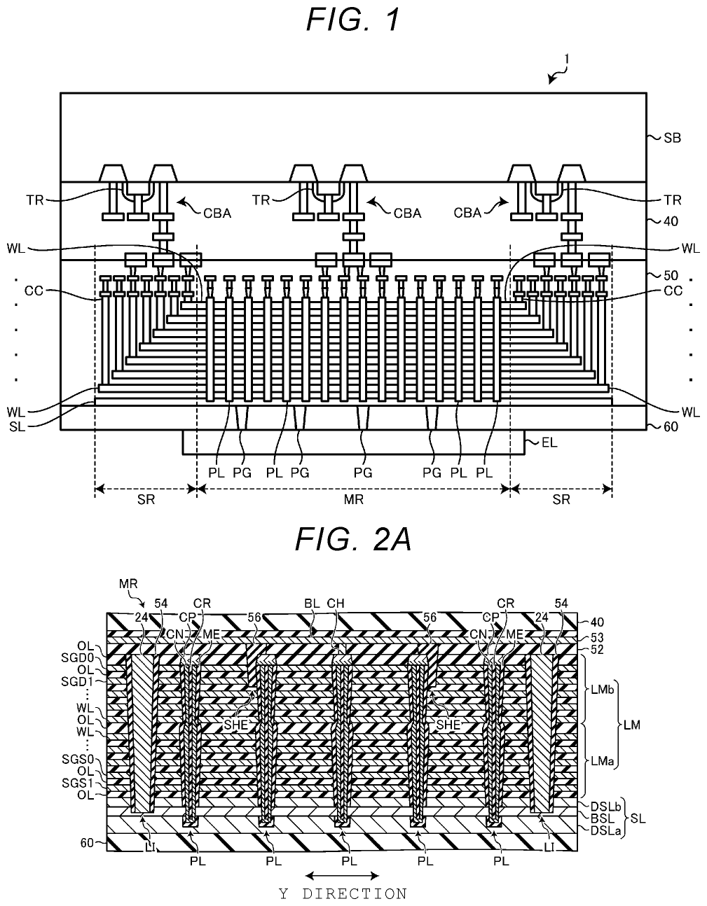

FIG. 1 is a cross-sectional view illustrating a schematic configuration example of a semiconductor memory device 1 according to the first embodiment. Note that, in FIG. 1, hatching is omitted considering the ease of viewing the drawing.

As illustrated in FIG. 1, the semiconductor memory device 1 includes, in order from the lower side of the paper, an electrode film EL, a source line SL, and a plurality of word lines WL. The semiconductor memory device 1 includes a peripheral circuit CBA provided on a semiconductor substrate SB above the plurality of word lines WL. In the description of FIG. 1, the side on which the semiconductor substrate SB is disposed is assumed to be the upper side of the semiconductor memory device 1.

The source line SL is disposed on the electrode film EL with an insulating layer 60 interposed therebetween. A plurality of plugs PG are disposed in the insulating layer 60, and electrical connection is maintained between the source line SL and the electrode film EL via the plugs PG. Although not illustrated, electrode pads for supplying power and signals to the semiconductor memory device 1 from the outside are provided in the same layer as the electrode film EL.

A plurality of word lines WL are stacked on the source line SL. A memory region MR is disposed at the center portion of the plurality of word lines WL, and staircase regions SR are disposed at both ends of the plurality of word lines WL.

A plurality of pillars PL penetrating the word lines WL in the stacking direction are disposed in the memory region MR. A plurality of memory cells are formed at intersections of the pillars PL and the word lines WL. Thereby, the semiconductor memory device 1 is configured as a three-dimensional nonvolatile memory in which memory cells are arranged three-dimensionally in the memory region MR, for example.

In the staircase region SR, a plurality of word lines WL are processed into a staircase shape and terminated. Contacts CC connected to the word lines WL of each level are disposed in a terrace portion of each level configured by the plurality of word lines WL.

The word lines WL stacked in multiple layers are individually drawn out by the contacts CC. From the contacts CC, write voltages, read voltages, and the like are applied to memory cells in the memory region MR at the center portion of the plurality of word lines WL via the word lines WL located at the same height as the memory cells.

The plurality of word lines WL, pillars PL, and contacts CC are covered with an insulating layer 50. The insulating layer 50 also extends around the plurality of word lines WL.

The semiconductor substrate SB above the insulating layer 50 is, for example, a silicon substrate. The peripheral circuit CBA including a transistor TR, wiring, and the like is disposed on the surface of the semiconductor substrate SB. Various voltages applied to the memory cells from the contacts CC are controlled by the peripheral circuit CBA electrically connected to the contacts CC. Thereby, the peripheral circuit CBA controls electrical operations of the memory cell.

The peripheral circuit CBA is covered with an insulating layer 40, and by bonding the insulating layer 40 to the insulating layer 50 covering a plurality of word lines WL and the like, the semiconductor memory device 1 is configured including the above configuration of the plurality of word lines WL, pillars PL, and contacts CC, and the peripheral circuit CBA.

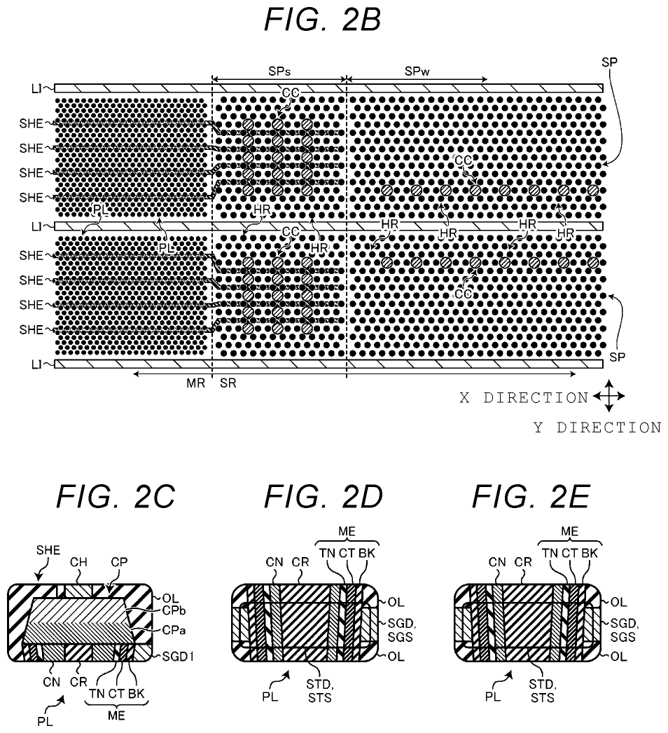

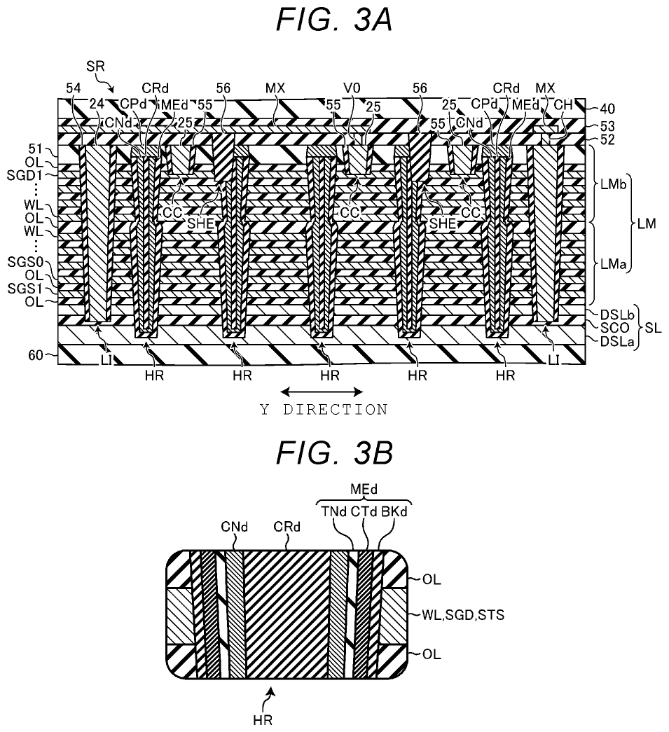

Next, a detailed configuration example of the semiconductor memory device 1 will be described using FIGS. 2A to 2E and 3A to 3B. FIGS. 2A to 2E and 3A to 3B are diagrams illustrating one example of the configuration of the semiconductor memory device 1 according to the first embodiment.

More specifically, FIG. 2A is a cross-sectional view along the Y direction of the semiconductor memory device 1 including the memory region MR. In FIG. 2A, the structure below the insulating layer 60 and above the insulating layer 40 is omitted. FIG. 2B is an XY cross-sectional view of a partial region of a stacked body LM at the height position of a selection gate line SGD.

FIGS. 2C to 2E are respectively an enlarged cross-sectional view of the upper end of the pillar PL, an enlarged cross-sectional view of the pillar PL at the height position of selection gate lines SGD and SGS, and an enlarged cross-sectional view of the pillar PL at the height position of the word line WL.

FIG. 3A is a cross-sectional view along the Y direction of the semiconductor memory device 1 including the staircase region SR. In FIG. 3A, the structure below the insulating layer 60 and above the insulating layer 40 is omitted. FIG. 3B is an enlarged cross-sectional view of a columnar portion HR at the height position of the word line WL or the selection gate lines SGD and SGS.

Note that the diagrams illustrated in FIGS. 2A to 2E and 3A to 3B are only schematic diagrams, and the layout of each part in the cross-sectional views along the Y direction in FIGS. 2A and 3A and the XY cross-sectional view in FIG. 2B does not necessarily match.

In the specification, both the X direction and the Y direction are directions along the plane of the word line WL, and the X direction and the Y direction are orthogonal to each other. The electrical draw direction of the word line WL may be referred to as a first direction, and the first direction is a direction along the X direction. A direction intersecting the first direction may be referred to as a second direction, and the second direction is a direction along the Y direction. However, since the semiconductor memory device 1 may include manufacturing errors, the first direction and the second direction are not necessarily orthogonal.

In the specification, of the selection gate lines SGD and SGS, which will be described later, the side where the drain side selection gate line SGD is disposed is defined as the upper side of the semiconductor memory device 1.

As illustrated in FIG. 2A, the source line SL has a multilayer structure in which, for example, a lower source line DSLa, an intermediate source line BSL, and an upper source line DSLb are stacked in this order on the insulating layer 60. Note that the intermediate source line BSL is disposed below the memory region MR of the stacked body LM.

The lower source line DSLa, the intermediate source line BSL, and the upper source line DSLb are, for example, polysilicon layers. Among the source lines, at least the intermediate source line BSL may be a conductive polysilicon layer or the like in which impurities are diffused.

The stacked body LM is disposed on the source line SL. The stacked body LM includes stacked bodies LMa and LMb in which a plurality of word lines WL and a plurality of insulating layers OL are alternately stacked one layer by one layer.

The stacked body LMa is disposed above the source line SL. A plurality of selection gate lines SGS0 and SGS1 are disposed in this order from the upper layer side of the stacked body LMa, further below the word line WL in the lowermost layer of the stacked body LMa, with the insulating layer OL interposed therebetween. The stacked body LMb is disposed on the stacked body LMa. A plurality of selection gate lines SGS and SGS1 are disposed in this order from the upper layer side of the stacked body LMb, further above the word line WL in the uppermost layer of the stacked body LMb, with the insulating layer OL interposed therebetween.

However, the number of stacked word lines WL and selection gate lines SGD and SGS as a plurality of conductive layers in the stacked body LM is freely selected. The word line WL and the selection gate lines SGD and SGS are made of, for example, a tungsten layer or a molybdenum layer. The insulating layer OL is, for example, a silicon oxide layer.

The upper surface of the stacked body LM is covered with an insulating layer 52. The insulating layer 52 is covered with an insulating layer 53. The insulating layers 52 and 53 each configure a part of the insulating layer 50 in FIG. 1 together with an insulating layer 51 described later.

As illustrated in FIG. 2B, the above-mentioned word line WL and selection gate lines SGD and SGS are processed into a staircase shape, so that the staircase region SR has a staircase portion SP including staircase portions SPs and SPw.

The staircase portion SPs is the uppermost layer portion of the stacked body LM, that is, a portion where the selection gate line SGD is processed into a staircase shape. The staircase portion SPw is a lower portion of the stacked body LM, that is, a portion where the word line WL and the selection gate line SGS are processed into a staircase shape.

The staircase portions SPs and SPw are disposed in the staircase region SR in this order to move away from the memory region MR. That is, as the distance from the memory region MR increases, the height position of the terrace portions of the staircase portions SPs and SPw decreases.

As illustrated in FIGS. 2A and 2B, the stacked body LM is divided in the Y direction by a plurality of plate-shaped contacts LI.

That is, each of the plate-shaped contacts LI is aligned with each other in the Y direction and extends in a direction along the stacking direction of the stacked body LM and the X direction. As such, the plate-shaped contact LI extends continuously within the stacked body LM from one end of the stacked body LM in the X direction to the other end. The plate-shaped contact LI penetrates through the stacked body LM and the upper source line DSLb, and reaches the intermediate source line BSL in the memory region MR.

The plate-like contact LI has a tapered shape, for example, such that the width in the Y direction decreases from the upper end to the lower end. Alternatively, the plate-like contact LI has a bowed shape in which the width in the Y direction is maximum at a predetermined position between the upper end and the lower end, for example.

Each plate-like contact LI includes an insulating layer 54 and a conductive layer 24. The insulating layer 54 is, for example, a silicon oxide layer. The conductive layer 24 is, for example, a tungsten layer or a conductive polysilicon layer.

The insulating layer 54 covers sidewalls of the plate-shaped contact LI that face each other in the Y direction. The conductive layer 24 is filled inside the insulating layer 54 and is electrically connected to the source lines SL including the intermediate source line BSL. The conductive layer 24 is connected to the upper layer wiring in a cross section different from that illustrated in FIG. 2A. With such configuration, the plate-like contact LI functions as a source line contact.

However, instead of the plate-shaped contact LI, a plate-shaped member filled with an insulating layer may penetrate the stacked body LM and extend in the direction along the X direction, thereby dividing the stacked body LM in the Y direction. Here, such plate member does not have a function as a source line contact.

In the memory region MR and the staircase portion SPs of the staircase region SR, a plurality of separation layers SHE penetrating the upper layer portion of the stacked body LM and extending in the direction along the X direction are disposed between the plate-shaped contacts LI adjacent in the Y direction. The separation layers SHE are insulating layers 56 such as silicon oxide layers that penetrate through selection gate lines SGD0 and SGD1 and reach the insulating layer OL directly below the selection gate line SGD1.

In other words, the separation layers SHE penetrating the upper layer portion of the stacked body LM extend in the memory region MR and the staircase portion SPs in the direction along the X direction between the plate-shaped contacts LI, so that the upper layer portion of the stacked body LM is separated in the Y direction and divided into the above-mentioned selection gate lines SGD0 and SGD1.

As illustrated in FIG. 2A, a plurality of pillars PL are distributed and located in the memory region MR, penetrating the stacked body LM, the upper source line DSLb, and the intermediate source line BSL to reach the lower source line DSLa.

The pillars PL as the plurality of first pillars are arranged, for example, in a staggered pattern when viewed from the stacking direction of the stacked body LM. Each pillar PL has for example, a circular shape, an elliptical shape, an oval shape, or the like as a cross-sectional shape in a direction along the layer direction of the stacked body LM, that is, in a direction along the XY plane.

The pillar PL has a tapered shape in which the diameter and the cross-sectional area decrease from the upper layer side to the lower layer side in the portion penetrating the stacked body LMa and the portion penetrating the stacked body LMb, respectively. Alternatively, the pillar PL has a bowed shape in which the diameter and the cross-sectional area are maximum at a predetermined position between the upper layer side and the lower layer side in the portion penetrating the stacked body LMa and the portion penetrating the stacked body LMb, respectively.

Each of the plurality of pillars PL includes a memory layer ME extending in the stacking direction within the stacked body LM, a channel layer CN penetrating through the stacked body LM and connected to the intermediate source line BSL, a cap layer CP covering the upper surface of the channel layer CN, and a core layer CR serving as a core material of the pillar PL.

As illustrated in FIGS. 2D and 2E, the memory layer ME has a multilayer structure in which a block insulating layer BK, a charge storage layer CT, and a tunnel insulating layer TN are stacked in this order from the outer peripheral side of the pillar PL. More specifically, the memory layer ME is disposed on the side surface of the pillar PL except for the depth position of the intermediate source line BSL. The memory layer ME is also disposed on the bottom surface of the pillar PL that reaches the depth of the lower source line DSLa.

The channel layer CN penetrates the stacked body LM, the upper source line DSLb, and the intermediate source line BSL inside the memory layer ME, and reaches the depth of the lower source line DSLa. More specifically, the channel layer CN is disposed on the side and bottom surfaces of the pillar PL with the memory layer ME interposed therebetween. However, a portion of the channel layer CN is in contact with the intermediate source line BSL on the side surface, and is thereby electrically connected to the source lines SL including the intermediate source line BSL. The core layer CR fills further inside the channel layer CN.

Each of the plurality of pillars PL includes the cap layer CP at the upper end. The cap layer CP is disposed at the upper end of the pillar PL to cover at least the upper end of the channel layer CN, and is connected to the channel layer CN. The cap layer CP is connected to a bit line BL disposed in the insulating layer 53 with a plug CH disposed in the insulating layer 52 interposed therebetween. The bit line BL extends above the stacked body LM in a direction along, for example, the X direction to intersect, for example, with the draw direction of the word line WL.

Note that in FIG. 2A, the plug CH is connected only to the pillar PL at the center of the paper. The other pillars PL are connected to other bit lines BL extending in the direction along the Y direction in parallel to the bit line BL illustrated in FIG. 2A at positions different from the cross section illustrated in FIG. 2A via the plug CH not illustrated in FIG. 2A.

The block insulating layer BK, the tunnel insulating layer TN, and the core layer CR of the memory layer ME are, for example, silicon oxide layers. The charge storage layer CT of the memory layer ME is, for example, a silicon nitride layer. The channel layer CN and the cap layer CP are semiconductor layers such as polysilicon layers or amorphous silicon layers, for example.

As illustrated in FIG. 2C, the cap layer CP includes cap layers CPa and CPb on the lower layer side in contact with the channel layer CN and on the upper layer side connected to the plug CH. Among the cap layers CPa and CPb, which are semiconductor layers or the like, the cap layer CPb is a dopant-containing layer containing a dopant.

The dopant contained in the cap layer CPb may include, for example, at least one of carbon and a P-type dopant. When the dopant contained in the cap layer CPb is carbon, the cap layer CPb may become a silicon carbide layer and be hardened. The P-type dopant contained in the cap layer CPb may include, for example, at least one of boron, gallium, and indium. Here, it is preferable that the P-type dopants are contained at a high concentration so that carriers are contained at a high density. Such cap layer CPb, which is hardened or contains carriers at a high density, has higher etching resistance than the cap layer CPa, as will be described later.

As illustrated in FIG. 2E, with the above configuration, memory cells MC are formed in the portions of the side surfaces of the pillars PL facing the respective word lines WL. By applying a predetermined voltage from the word line WL, data is written to and read from the memory cell MC.

As illustrated in FIG. 2D, selection gates STD are formed in portions where the side surfaces of the pillars PL face the selection gate lines SGD0 and SGD1 disposed above the word line WL, respectively. Selection gates STS are formed in portions where the side surfaces of the pillars PL face the selection gate lines SGS0 and SGS1 disposed below the word line WL, respectively.

By applying predetermined voltages from the selection gate lines SGD and SGS, the selection gates STD and STS are turned on or off, and the memory cells MC of the pillars PL to which the selection gates STD and STS belong can be in a selected state or an unselected state.

Here, at least a portion of the above-mentioned separation layer SHE may be disposed at a position overlapping a portion of some pillars PL in the stacking direction. Here, the separation layer SHE overlaps the pillar PL at any one of both ends of the pillar PL in the direction along the Y direction.

In the portion where the separation layer SHE and the pillar PL overlap, the lower end of the separation layer SHE is located on the upper surface of the cap layer CPb at the upper end of the pillar PL. That is, in the portion overlapping with the pillar PL, the separation layer SHE does not extend below the upper surface of the cap layer CPb within the stacked body LM.

Therefore, even in the pillar PL partially overlapping with the separation layer SHE, the functions of the memory cell MC and the selection gates STD and STS are maintained. That is, even in the pillar PL overlapping with the separation layer SHE, the functions of the memory cells MC and selection gates STS located at the height of the word line WL and selection gate line SGS lower than the selection gate line SGD are not affected at all.

When one end side of the pillar PL in the direction along the Y direction overlaps with the separation layer SHE, the other end side is in contact with the selection gate line SGD, and the contact portion between the pillar PL and the selection gate line SGD can function as the selection gate STD belonging to a section of the selection gate line SGD.

As illustrated in FIG. 3A, the stacked body LM in the staircase region SR is covered with the insulating layer 51. The insulating layer 51 reaches, for example, the height position of the uppermost layer of the stacked body LM in the memory region MR, and the insulating layers 52 and 53 also cover the upper surface of the insulating layer 51. As mentioned above, the insulating layer 51 also configures a portion of the insulating layer 50 of FIG. 1.

In the staircase region SR, the source line SL includes an intermediate insulating layer SCO interposed between the upper source line DSLb and the lower source line DSLa, instead of the intermediate source line BSL. The intermediate insulating layer SCO is, for example, a silicon oxide layer.

Therefore, in the staircase region SR, the plate-shaped contact LI penetrates through the insulating layer 51, the stacked body LM, and the upper source line DSLb to reach the intermediate insulating layer SCO. In the staircase region SR, the upper end of the plate-shaped contact LI is connected to an upper layer wiring MX disposed in the insulating layer 53 via the plug CH disposed in the insulating layer 52.

In the staircase region SR, the contact CC and a plurality of columnar portions HR are disposed. As will be described later, the columnar portions HR have a role of supporting these structures when the stacked body LM is formed from a stacked body in which a sacrifice layer and an insulating layer are stacked, and does not contribute to the functions of the semiconductor memory device 1.

Each contact CC penetrates the insulating layer 51 and is connected to the word line WL or selection gate lines SGD and SGS directly below the insulating layer OL forming each level of the staircase portion SP.

Each contact CC has, for example, a tapered shape in which the diameter and the cross-sectional area become smaller from the upper end to the lower end. Alternatively, the contact CC has a bowed shape in which the diameter and the cross-sectional area are the maximum at a predetermined position between the upper end and the lower end, for example.

The contact CC includes an insulating layer 55 covering the outer periphery of the contact CC, and a conductive layer 25 such as a tungsten layer or a copper layer filled inside the insulating layer 55. The conductive layer 25 is connected to the upper layer wiring MX disposed in the insulating layer 53 via a plug V0 disposed in the insulating layer 52. The upper layer wiring MX is electrically connected to the above-mentioned peripheral circuit CBA (see FIG. 1).

With such configuration, the word line WL in each layer of the stacked body LM and the selection gate lines SGD and SGS in the layers above and below the word line WL can be electrically drawn out. That is, with the above configuration, a predetermined voltage can be applied to the memory cell MC from the peripheral circuit CBA via the upper layer wiring MX, the contact CC, the word line WL, and the like, and the memory cell MC can be operated as a storage element.

Note that FIG. 3A illustrates a portion of the selection gate line SGD1 that is processed into a staircase shape in the staircase portion SPs among the staircase portions SPs and SPw in which the plurality of word lines WL and selection gate lines SGD and SGS are processed into a staircase shape. In the cross section illustrated in FIG. 3A, the selection gate line SGD1 is separated into a plurality of parts in the Y direction by a plurality of separation layers SHE penetrating the selection gate line SGD1, and the contact CC is connected to each of the separated sections of the respective selection gate lines SGD1.

That is, in FIG. 3A, the insulating layer OL directly above the selection gate line SGD1 is a terrace surface, and the contact CC penetrates the insulating layer OL to be connected to the selection gate line SGD1. By applying a predetermined voltage to a corresponding section of the selection gate line SGD1 from any of the contacts CC, the memory cell MC of the pillar PL corresponding to the section can be brought into a selected state.

As illustrated in FIGS. 3A and 2B, in the staircase region SR, a plurality of columnar portions HR that penetrate the insulating layer 51, the stacked body LM, the upper source line DSLb, and the intermediate insulating layer SCO to reach the lower source line DSLa are distributed and arranged.

The columnar portions HR as the plurality of second pillars are arranged in, for example, a grid shape or a staggered pattern when viewed from the stacking direction of the stacked body LM while avoiding interference with the plate contacts LI and the contacts CC. Each columnar portion HR has, for example, a circular, elliptical, or oval shape as a cross-sectional shape in the direction along the XY plane.

The columnar portion HR has a tapered shape in which the diameter and the cross-sectional area decrease from the upper layer side to the lower layer side in the portion penetrating the stacked body LMa and the portion penetrating the stacked body LMb, respectively. Alternatively, the columnar portion HR has a bowed shape in which the diameter and the cross-sectional area are maximum at a predetermined position between the upper layer side and the lower layer side in the portion penetrating the stacked body LMa and the portion penetrating the stacked body LMb, respectively.

Each of the plurality of columnar portions HR has the same layer structure as the pillar PL described above. However, the plurality of columnar portions HR are in a floating state as a whole, and have no electrical function in the semiconductor memory device 1, as described above.

By disposing the columnar portion HR as described above while avoiding interference with plate-shaped contacts LI and the contacts CC, the effect of contact of the columnar portion HR, which has a layer structure similar to that of the pillar PL, with the plate-shaped contacts LI and the contacts CC is reduced.

The columnar portion HR has the same layer structure as the pillar PL, and includes dummy layers MEd, CNd, and CRd extending in the stacking direction within the stacked body LM.

As illustrated in FIG. 3B, the dummy layer MEd has a multilayer structure in which dummy layers BKd, CTd, and TNd are stacked in this order from the outer peripheral side of the columnar portion HR. In other words, the dummy layer MEd corresponds to the memory layer ME of the pillar PL described above. The dummy layers BKd, CTd, and TNd in the dummy layer MEd correspond to the block insulating layer BK, the charge storage layer CT, and the tunnel insulating layer TN of the pillar PL, respectively.

However, the dummy layer MEd is disposed without interruption on the side surface of the columnar portion HR from the upper source line DSLb to the lower source line DSLa. The dummy layer MEd is also disposed at the lower end of the columnar portion HR.

The dummy layer CNd penetrates the stacked body LM, the upper source line DSLb, and the intermediate insulating layer SCO inside the dummy layer MEd, and reaches the depth of the lower source line DSLa. The dummy layer CNd corresponds to the channel layer CN of the pillar PL described above.

However, the dummy layer MEd is disposed on the side surface of the dummy layer CNd extending from the upper source line DSLb to the lower source line DSLa, and the dummy layer CNd is not in direct contact with the intermediate insulating layer SCO. The dummy layer CRd fills further inside the dummy layer CNd. The dummy layer CRd corresponds to the core layer CR of the pillar PL described above.

Each of the plurality of columnar portions HR includes a dummy layer CPd at the upper end. The dummy layer CPd is disposed at the upper end of the columnar portion HR to cover at least the upper end of the dummy layer CNd, and is connected to the dummy layer CNd. As such, the dummy layer CPd corresponds to the cap layer CP of the pillar PL described above. Note that the columnar portion HR may not include the dummy layer CPd.

Each layer in the columnar portion HR includes the same kind of material as each layer of the corresponding pillar PL. That is, the dummy layers BKd and TNd of the dummy layer MEd, and the dummy layer CRd are, for example, silicon oxide layers. The dummy layer CTd is, for example, a silicon nitride layer. The dummy layers CNd and CPd are semiconductor layers such as polysilicon layers or amorphous silicon layers, for example.

However, unlike the cap layer CP of the pillar PL, the dummy layer CPd of the columnar portion HR does not have a layer containing a dopant in the upper layer portion. That is, the entire dummy layer CPd of the columnar portion HR has the same material as, for example, the cap layer CPa of the pillar PL.

Here, at least a portion of the above-mentioned separation layer SHE may be disposed at a position overlapping a portion of some columnar portion HR in the stacking direction. In the portion where the separation layer SHE and the columnar portion HR overlap, the separation layer SHE erodes the columnar portion HR and extends in the depth direction within the columnar portion HR. As a result, the columnar portion HR is partially cut out in the portion overlapping with the separation layer SHE.

Note that at the same height position of the stacked body LM, the cross-sectional area of the columnar portion HR in the direction along the XY plane is larger than, for example, the cross-sectional area of the pillar PL in the direction along the XY plane. The pitch between the plurality of columnar portions HR is larger than, for example, the pitch between the plurality of pillars PL, and the arrangement density of the columnar portions HR per unit area of the word line WL in the stacked body LM is lower than the arrangement density of pillars PL per unit area of the word line WL.

As such, for example, by configuring the cross-sectional area of the pillar PL to be smaller and the pitch to be narrower compared to the columnar portion HR, it is possible to form a large number of memory cells MC at high density in the stacked body LM of a predetermined size. Therefore, the storage capacity of the semiconductor memory device 1 can be increased. On the other hand, since the columnar portions HR are used exclusively to support the stacked body LM, the manufacturing load can be reduced by not having a precise configuration with a small cross-sectional a and narrow pitches like the pillars PL, for example.

### Method for Manufacturing Semiconductor Memory Device

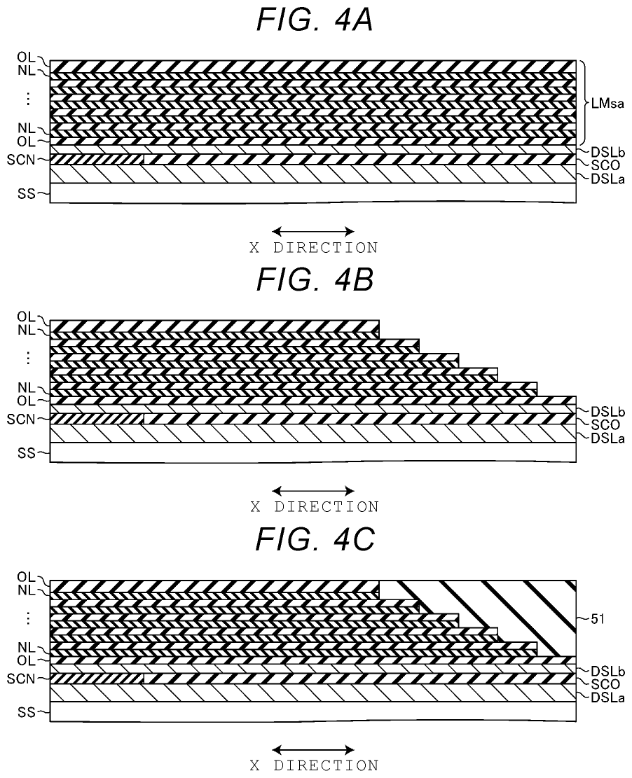

Next, a method for manufacturing the semiconductor memory device 1 of the first embodiment will be described with reference to FIGS. 4A to 11C. FIGS. 4A to 11C are diagrams sequentially illustrating a part of the procedure of the manufacturing method of the semiconductor memory device 1 according to the first embodiment.

First, FIGS. 4A to 4C illustrate how a configuration that will later become the staircase portion SPw is formed in a stacked body LMsa, which is the lower layer portion of the stacked body LM before the word line WL is formed. FIGS. 4A to 4C are cross-sectional views along the X direction of the semiconductor memory device 1 during manufacturing.

As illustrated in FIG. 4A, the lower source line DSLa, the intermediate sacrifice layer SCN or the intermediate insulating layer SCO, and the upper source line DSLb are formed in this order on a support substrate SS.

As the support substrate SS, a semiconductor substrate such as a silicon substrate, an insulating substrate such as a ceramic substrate, a conductive substrate such as an alumina substrate, or the like may be used. An insulating layer 60 may be formed on the upper surface side of the support substrate SS.

The intermediate sacrifice layer SCN is formed in a region on the support substrate SS that will later become the memory region MR, and the intermediate insulating layer SCO is formed in a region on the support substrate SS that will later become the staircase region SR. The intermediate sacrifice layer SCN is, for example, a silicon nitride layer or the like, and is a layer that will later be replaced with a polysilicon layer or the like to become the intermediate source line BSL. As described above, the intermediate insulating layer SCO is, for example, a silicon oxide layer.

The stacked body LMsa in which a plurality of insulating layers NL and a plurality of insulating layers OL are alternately stacked one layer by one layer is formed on the upper source line DSLb. The insulating layer NL is, for example, a silicon nitride layer or the like, and functions as a sacrifice layer that is later replaced with a conductive material to become the word line WL or the selection gate line SGS.

As illustrated in FIG. 4B, in a partial region of the stacked body LMsa, the insulating layer NL and the insulating layer OL are processed into a staircase shape. Such staircase-shaped structure is formed by repeating slimming of a mask pattern such as a photoresist layer and etching of the insulating layer NL and the insulating layer OL of the stacked body LMsa a plurality of times.

That is, a mask pattern is formed on the upper surface of the stacked body LMsa, and, for example, the exposed portions of the insulating layer NL and the insulating layer OL are removed by etching one by one. By treatment using oxygen plasma or the like, the end of the mask pattern is retreated to newly expose the upper surface of the stacked body LMsa, and the insulating layer NL and the insulating layer OL are further removed by etching one by one. By repeating the process a plurality of times, the staircase-shaped structure described above is formed.

As illustrated in FIG. 4C, the insulating layer 51 is formed to cover the staircase-shaped structure and reach the height of the upper surface of the unprocessed portion of the stacked body LMsa. The insulating layer 51 is also formed in the outer region of the stacked body LMsa.

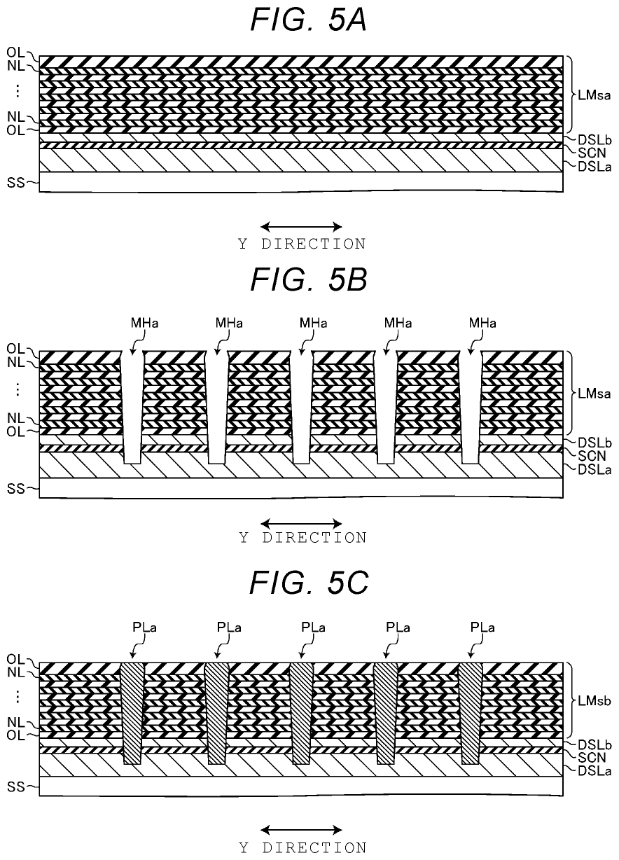

Next, FIGS. 5A to 5C illustrate how a configuration that will later become a part of the pillar PL is formed. FIGS. 5A to 5C are cross-sectional views along the Y direction of a region that will later become the memory region MR.

As illustrated in FIG. 5A, the unprocessed stacked body LMsa is already formed in a region that will later become the memory region MR.

As illustrated in FIG. 5B, a plurality of memory holes MHa are formed in the stacked body LMsa extending in the stacking direction. The plurality of memory holes MHa penetrate the stacked body LMsa, the upper source line DSLb, and the intermediate sacrifice layer SCN to reach the lower source line DSLa. The memory hole MHa is a portion that will later become the lower structure of the pillar PL.

As illustrated in FIG. 5C, the memory holes MHa are filled with a CVD-carbon layer or a sacrifice layer such as amorphous silicon. As a result, a pillar PLa is formed in which the plurality of memory holes MHa are filled with the sacrifice layer.

Note that the CVD-carbon layer is an organic layer formed by, for example, a chemical vapor deposition (CVD) method using a carbon-containing gas. The CVD-carbon layer has higher hardness than, for example, a photoresist layer which is also an organic layer, and can be removed by ashing using oxygen plasma or the like.

Although not illustrated, in the region that later becomes the staircase region SR, the same process as in FIGS. 5A to 5C above is performed in parallel to form a plurality of columnar structures configured of sacrifice layers that later become the lower structure of the columnar portion HR.

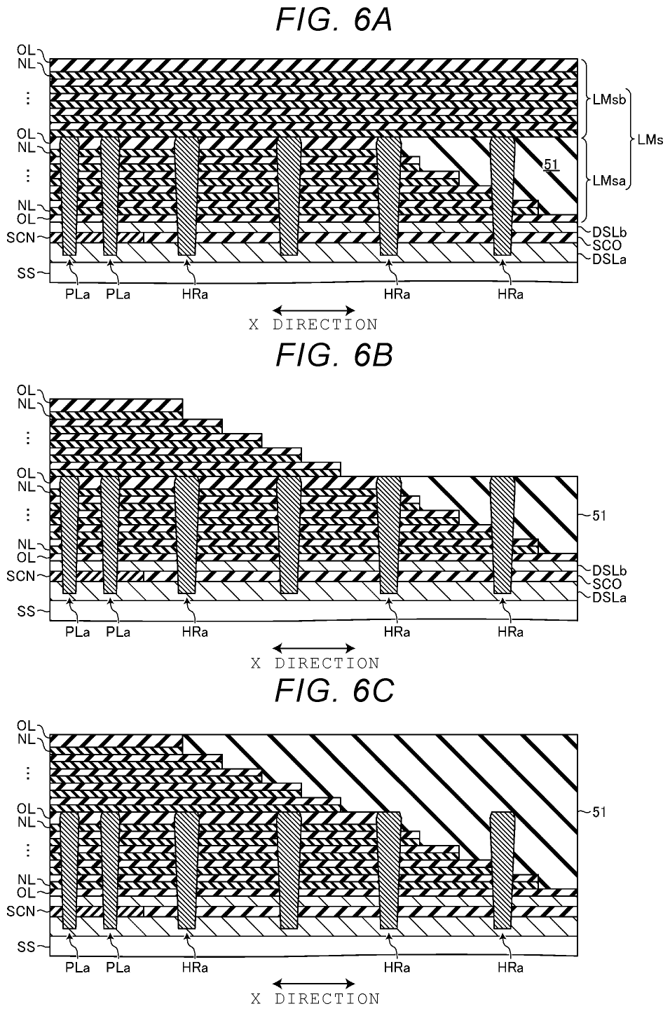

Next, FIGS. 6A to 6C illustrate how a configuration that will later become the staircase portions SPw and SPs are formed in a stacked body LMsb, which is the upper layer portion of the stacked body LM before the word line WL is formed. FIGS. 6A to 6C are cross-sectional views along the X direction of the semiconductor memory device 1 during manufacturing, similar to FIGS. 4A to 4C described above.

As illustrated in FIG. 6A, a sacrifice layer columnar structure HRa, which will later become a lower structure of the columnar portion HR, is already formed in the portion of the stacked body LMsa where the staircase-shaped structure is formed.

The stacked body LMsa and the insulating layer 51 covering the staircase-shaped structure are covered to form the stacked body LMsb in which a plurality of insulating layers NL and a plurality of insulating layers OL are alternately stacked one layer by one layer. The sacrifice layer NL of the stacked body LMsb is later replaced with a conductive layer and becomes the word line WL or the selection gate line SGD. As a result, the stacked body LMs including the stacked body LMsa and the stacked body LMsb is formed.

As illustrated in FIG. 6B, in a partial region of the stacked body LMsb, the insulating layer NL and the insulating layer OL are processed into a staircase shape. Such staircase structure is formed by repeating slimming of a mask pattern such as a photoresist layer and etching of the insulating layer NL and the insulating layer OL of the stacked body LMsb a plurality of times, similar to the process illustrated in FIG. 4B described above.

Here, the uppermost level of the staircase structure already formed in the stacked body LMsa and the lowermost level of the staircase structure in the stacked body LMsb are brought close to each other. Thereby, the staircase structure that will later become the staircase portions SPw and SPs is disposed to be continuous from the lower layer side to the upper layer side of the stacked body LMs.

As illustrated in FIG. 6C, the insulating layer 51 is further stacked to cover the staircase structure of the newly formed stacked body LMsb.

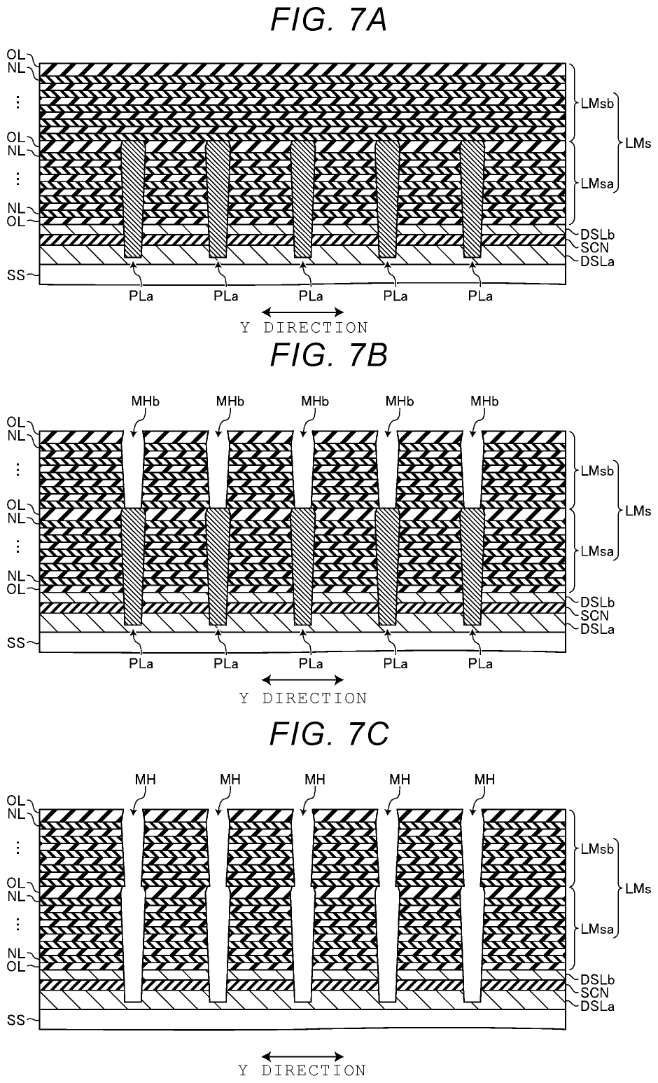

Next, FIGS. 7A to 9C illustrate how the pillar PL is formed. Similar to FIGS. 5A to 5C described above, FIGS. 7A to 9C are cross-sectional views along the Y direction of a region that will later become the memory region MR.

As illustrated in FIG. 7A, the unprocessed stacked body LMsb is already formed in a region that will later become the memory region MR.

As illustrated in FIG. 7B, a plurality of memory holes MHb are formed in the stacked body LMsb extending in the stacking direction. The plurality of memory holes MHb penetrate the stacked body LMsb and reach the upper ends of the pillars PLa formed in the stacked body LMsa. The memory hole MHb is a portion that will later become the upper structure of the pillar PL.

As illustrated in FIG. 7C, the sacrifice layer of the pillar PLa is removed through the memory hole MHb. When the sacrifice layer is a CVD-carbon layer or the like, it is possible to remove the sacrifice layer by ashing using oxygen plasma or the like. When the sacrifice layer is an amorphous silicon layer or the like, it is possible to remove the sacrifice layer by wet etching or the like.

Thereby, a memory hole MH is formed that penetrates the stacked body LMs and reaches the lower source line DSLa.

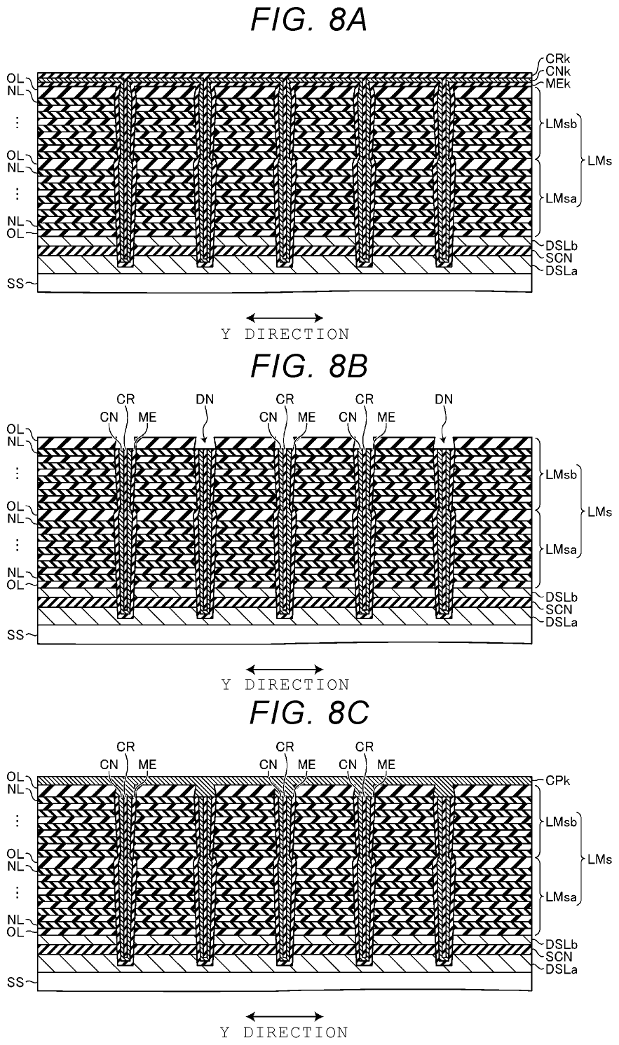

As illustrated in FIG. 8A, a multilayer insulating layer MEk, a semiconductor layer CNk, and an insulating layer CRk are formed in this order in the memory hole MH. The multilayer insulating layer MEk is an insulating layer with a multilayer structure that will later become the memory layer ME. The semiconductor layer CNk is a layer that will later become the channel layer CN. The insulating layer CRk is a silicon oxide layer or the like that will later become the core layer CR.

As a result, the multilayer insulating layer MEk and the semiconductor layer CNk are disposed on the side surface of the memory hole MH and the bottom surface where the lower source line DSLa is exposed, and the center portion of the memory hole MH is filled with the insulating layer CRk. The multilayer insulating layer MEk, the semiconductor layer CNk, and the insulating layer CRk are also formed in this order on the upper surface of the stacked body LMs.

As illustrated in FIG. 8B, the insulating layer CRk, the semiconductor layer CNk, and the multilayer insulating layer MEk are sequentially etched back to remove the layers from the upper surface of the stacked body LMs, and a depression DN is formed at the upper end of the memory hole MH.

As a result, the memory layer ME, the channel layer CN, and the core layer CR are formed in the memory hole MH in this order from the outer peripheral side.

As illustrated in FIG. 8C, a semiconductor layer CPk is formed in the depression DN at the upper end of the memory hole MH. The semiconductor layer CPk is a layer that will later become the cap layer CP. The semiconductor layer CPk is also formed on the upper surface of the stacked body LMs.

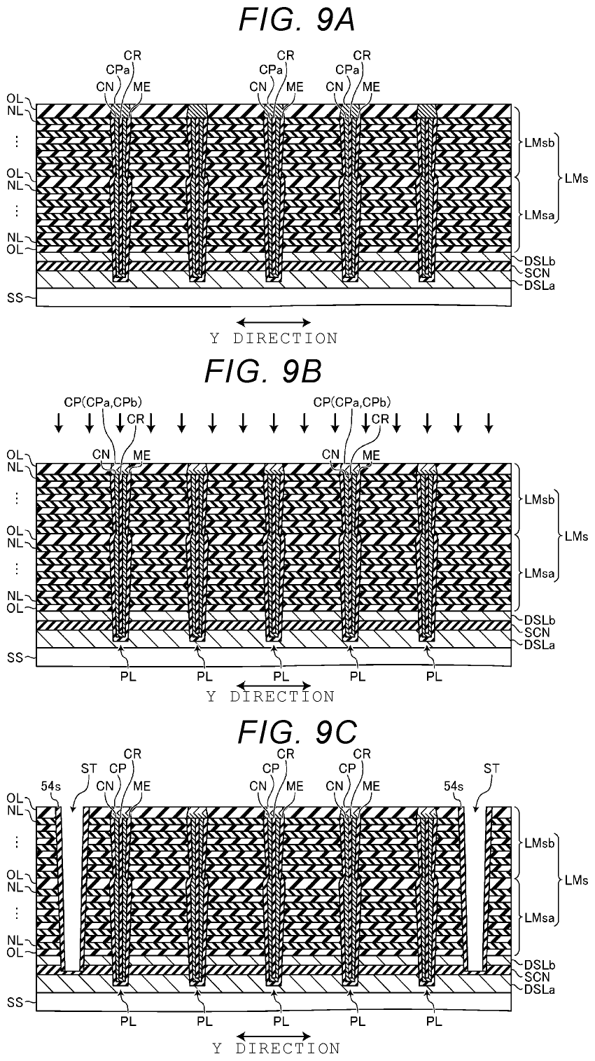

As illustrated in FIG. 9A, the semiconductor layer CPk on the upper surface of the stacked body LMs is removed by chemical mechanical polishing (CMP) or the like, and the cap layer CPa is formed at the upper end of the memory hole MH. That is, here, no dopant is implanted into the semiconductor layer CPk, and the entire semiconductor layer CPk filled in the depression DN is in the state of the cap layer CPa.

As illustrated in FIG. 9B, at least one of a dopant such as carbon and a P-type dopant such as boron, gallium, and indium is contained in the surface layer portion of the cap layer CPa by, for example, ion implantation. As a result, the surface layer portion of the cap layer CPa becomes hard or contains carriers at a high density, and becomes the cap layer CPb as a first layer containing a predetermined dopant.

Thereby, the pillar PL including the cap layers CPa and CPb at the upper end is formed. However, here, the memory layer ME covers the entire sidewall of the pillar PL, and the side surface of the channel layer CN is not exposed.

Although not illustrated, in the region that will later become the staircase region SR, the same processes as in FIGS. 7A to 9C described above are performed in parallel, and a plurality of columnar portions HR are formed. However, since the columnar portion HR has a dummy structure, no dopant is implanted into the dummy layer CPd corresponding to the cap layer CP of the pillar PL. Alternatively, the configuration corresponding to the cap layer CP of the pillar PL may not be formed in the columnar portion HR. In this case, the depression generated by the etch-back at the upper end of the columnar portion HR may be buried back with, for example, a silicon oxide layer.

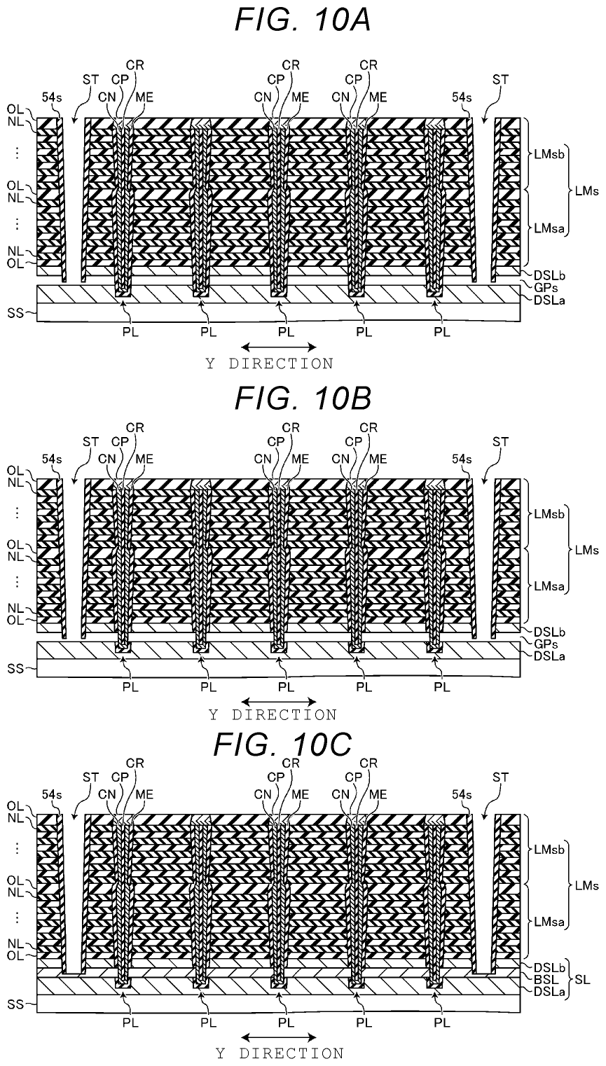

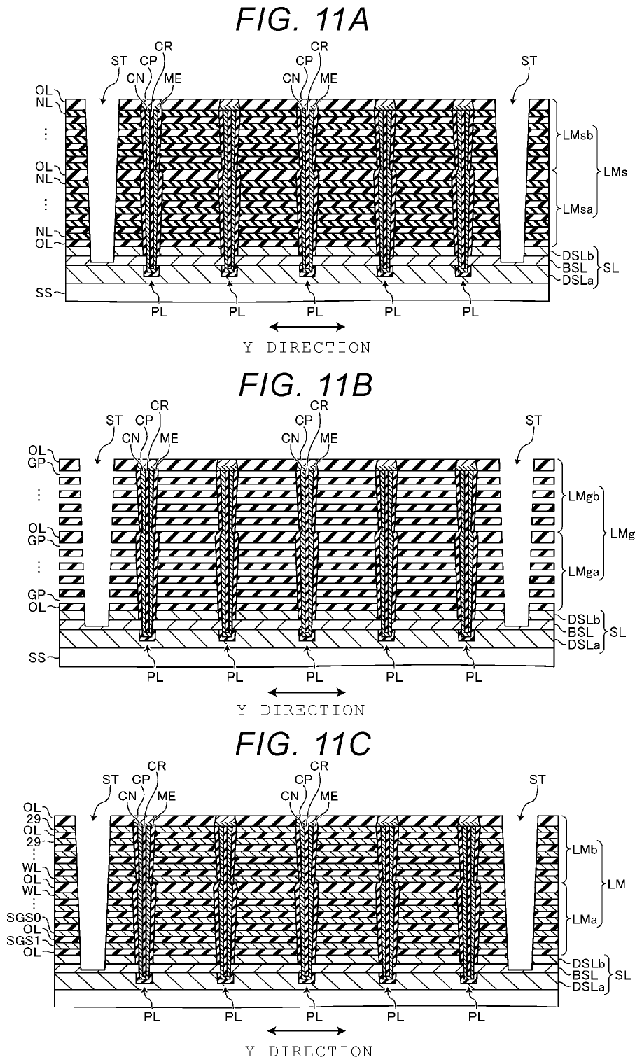

Next, the formation of the source line SL and the word line WL will be illustrated using FIGS. 9C to 11C. Similar to FIGS. 7A to 9C described above, FIGS. 10A to 11C are cross-sectional views along the Y direction of a region that will later become the memory region MR.

As illustrated in FIG. 9C, a slit ST is formed that penetrates the stacked body LMs and the upper source line DSLb and reaches the intermediate sacrifice layer SCN. The slit ST has a tapered or bowed vertical cross section in the Y direction, and also extends in the depth direction of the paper, that is, in the direction along the X direction. Therefore, although not illustrated, in the region that will later become the staircase region SR, the lower end of the slit ST reaches the intermediate insulating layer SCO.

An insulating layer 54s is formed on the sidewalls of the slit ST facing each other in the Y direction. The insulating layer 54s is, for example, a silicon oxide layer or the like, and is a temporary protective layer formed to protect the stacked body LMs in the subsequent processing, unlike the above-mentioned insulating layer 54 (see FIG. 2A and the like) in which the plate-shaped contact LI will later have on the sidewall.

As illustrated in FIG. 10A, a removing solution for the intermediate sacrifice layer SCN, such as hot phosphoric acid, is poured through the slit ST whose sidewall is protected by the insulating layer 54s, thereby removing the intermediate sacrifice layer SCN interposed between the lower source line DSLa and the upper source line DSLb.

Thereby, a gap layer GPs is formed between the lower source line DSLa and the upper source line DSLb. A part of the memory layer ME at the outer periphery of the pillar PL is exposed in the gap layer GPs.

Here, since the sidewall of the slit ST is protected by the insulating layer 54s, even the insulating layer NL in the stacked body LMs is prevented from being removed. In the not-illustrated staircase region SR, there is no sacrifice layer SCN between the lower source line DSLa and the upper source line DSLb, and no gap layer GPs is formed.

As illustrated in FIG. 10B, a chemical solution is appropriately poured into the gap layer GPs through the slit ST, and the block insulating layer BK, the charge storage layer CT, and the tunnel insulating layer TN (see FIGS. 2D and 2E) of the memory layer ME exposed in the gap layer GPs are sequentially removed. As a result, the memory layer ME is removed from a portion of the sidewall of the pillar PL, and a portion of the inner channel layer CN is exposed within the gap layer GPS.

As illustrated in FIG. 10C, a source gas such as amorphous silicon is injected through the slit ST whose sidewall is protected by the insulating layer 54s, and the gap layer GPs is filled with amorphous silicon or the like. The support substrate SS is heat-treated to polycrystallize the amorphous silicon filled in the gap layer GPs to the intermediate source line BSL containing polysilicon or the like.

Thereby, a part of the channel layer CN of the pillar PL is connected to the source line SL at the side surface via the intermediate source line BSL.

Here, in the not-illustrated staircase region SR, no gap layer GPs is formed between the lower source line DSLa and the upper source line DSLb. Therefore, for example, the dummy layer MEd of the columnar portion HR is not removed, and the intermediate source line BSL is not formed.

It is preferable that the columnar portion HR, which is a dummy pillar, has no electrical connection with the source line SL. As described above, in the staircase region SR excluding the memory region MR, by disposing the intermediate insulating layer SCO instead of the intermediate sacrifice layer SCN between the lower source line DSLa and the upper source line DSLb, the columnar portion HR is prevented from being connected with the source line SL.

As illustrated in FIG. 11A, the insulating layer 54s on the sidewall of the slit ST is once removed.

As illustrated in FIG. 11B, a removing solution for the insulating layer NL, such as hot phosphoric acid, is poured into the stacked body LMs from the slit ST to remove the insulating layer NL of the stacked body LMs. As a result, a stacked body LMg including stacked bodies LMga and LMgb having a plurality of gap layers GP from which the insulating layer NL between the insulating layers OL is removed is formed.

Note that the stacked body LMg including the plurality of gap layers GP has a fragile structure. In a region that will later become the memory region MR, a plurality of pillars PL support the fragile stacked body LMg. On the other hand, in a region that will later become the staircase region SR, a plurality of columnar portions HR support the stacked body LMg.

The support structure of the pillar PL and the columnar portion HR prevents the remaining insulating layer OL from being bent and the stacked body LMg itself from being distorted or collapsed.

As illustrated in FIG. 11C, a raw material gas of a conductive material such as tungsten or molybdenum is injected into the stacked body LMg from the slit ST, and the gap layer GP of the stacked body LMg is filled with the conductive material to form the word line WL and the like. As a result, the stacked body LM including the stacked bodies LMa and LMb in which a plurality of word lines WL or the like and a plurality of insulating layers OL are alternately stacked one layer by one layer is formed.

Note that the uppermost conductive layer 29 and the second uppermost conductive layer 29 of the stacked body LMb are divided into patterns of a plurality of selection gate lines SGD by forming the separation layer SHE penetrating the conductive layers later.

As described above, the process of forming the intermediate source line BSL from the intermediate sacrifice layer SCN and the process of forming the word line WL from the insulating layer NL are also called replacement process.

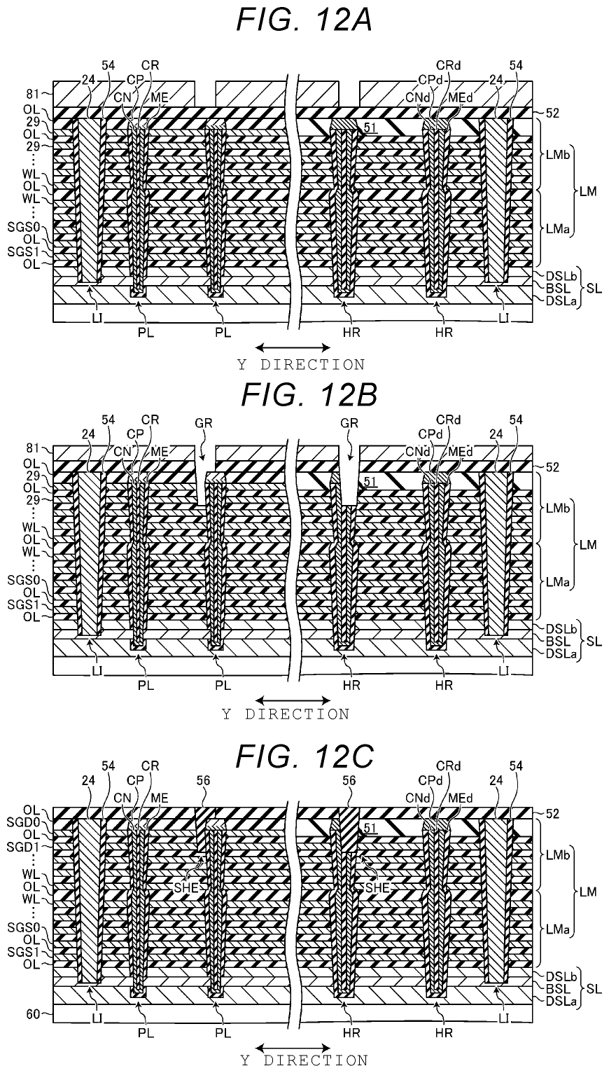

Next, using FIGS. 12A to 12C, how the separation layer SHE is formed and the conductive layer 29 is divided into a pattern of the selection gate lines SGD will be illustrated. FIGS. 12A to 12C are cross-sectional views along the Y direction including both regions that will later become the memory region MR and the staircase region SR.

Note that the cross section of the region that will later become the staircase region SR shows the staircase portion SPs with a terrace surface directly above the second uppermost conductive layer 29 of the stacked body LMb, as in FIG. 3A above.

As illustrated in FIG. 12A, the insulating layer 54 is formed on the sidewall of the slit ST, and a conductive layer 24 is filled in the insulating layer 54 to form the plate-shaped contact LI that becomes a source line contact. However, the slit ST may be filled with the insulating layer 54 or the like without forming the conductive layer 24, thereby forming a plate-shaped member that does not function as a source line contact.

The insulating layer 52 is formed on the upper surface of the stacked body LM, and a resist pattern 81 is further formed on the upper surface of the insulating layer 52. The resist pattern 81 is an organic layer such as a photoresist layer having a pattern of the separation layer SHE, and can be removed by, for example, ashing using oxygen plasma.

As illustrated in FIG. 12B, using the resist pattern 81 as a mask, a groove GR is formed that penetrates one or a plurality of conductive layers 29 including the uppermost conductive layer 29 of the stacked body LMb. Here, at least a portion of the groove GR may be formed at a position overlapping a portion of the pillar PL and the columnar portion HR.

At this time, as described above, the cap layer CPb which is hardened by implanting a dopant, or contains carriers at a high density is formed on the upper end of the pillar PL. For example, when forming the groove GR by reactive ion etching (RIE) or the like, the hardened cap layer CPb exhibits higher etching resistance than the cap layer CPa that does not contain a dopant. In the cap layer CPb containing carriers at a high density, the carriers can inhibit the etching reaction at the crystal surface of the cap layer CPb, which is a semiconductor layer or the like. As a result, the cap layer CPb containing carriers at a high density also exhibits higher etching resistance than the cap layer CPa.

As described above, when forming the groove GR, the cap layer CPb that acquired etching resistance functions as a stopper layer, and at the position overlapping with the pillar PL, the lower end of the groove GR remains on the upper surface of the cap layer CPb without eroding the pillar PL in the depth direction. As a result, even when the pillar PL overlaps with the groove GR, each configuration of the pillar PL remains as it is, and the functions as the memory cell MC and the selection gates STD and STS are maintained.

On the other hand, as described above, the configuration corresponding to the cap layer CPb of the pillar PL is not formed at the upper end of the columnar portion HR, but, for example, the dummy layer CPd, which is a semiconductor layer containing no dopant, is formed. Therefore, when forming the groove GR by RIE or the like, the groove GR extends in the stacking direction inside the columnar portion HR while eroding the columnar portion HR in the depth direction at the position overlapping with the columnar portion HR. As a result, when the columnar portion HR overlaps with the groove GR, a portion of the configuration of the columnar portion HR is cut off. As described above, since the columnar portion HR has a dummy configuration, the characteristics of the semiconductor memory device 1 are not affected by cut-off.

Thereafter, the resist pattern 81 is removed by, for example, ashing using oxygen plasma.

As illustrated in FIG. 12C, the separation layer SHE is formed by filling the groove GR with the insulating layer 56. As a result, the conductive layers 29 penetrated by the groove GR are divided into patterns of selection gate lines SGD.

After that, a plurality of contact holes penetrating the insulating layer 51 and respectively reaching the word line WL and selection gate lines SGD and SGS configuring each level of the staircase portion SP are formed at once, and the insulating layer 55 and the conductive layer 25 are formed in the contact hole. As a result, the contacts CC are formed which are respectively connected to the plurality of word lines WL and selection gate lines SGD and SGS.

Subsequently, the insulating layer 52 is formed on the upper surface of the stacked body LM and the upper surface of the insulating layer 51 covering the staircase region SR, and the plug V0 is formed to penetrate through the insulating layer 52 and to be connected to the contact CC. A plug CH is formed to penetrate through the insulating layer 52 and to be connected to the plate-shaped contact LI and the cap layer CPb of the pillar PL. Further, the insulating layer 53 is formed on the insulating layer 52, and the upper layer wiring MX, the bit line BL, and the like connected to the plugs V0 and CH are formed. On the upper surface of the insulating layer 53, electrode pads and the like are formed for establishing electrical connection with the peripheral circuit CBA.

Note that the plugs V0 and CH, the upper layer wiring MX, the bit line BL, and the like may be formed all at once by using, for example, a dual damascene method or the like.

The peripheral circuit CBA is formed on the semiconductor substrate SB that is separate from the support substrate SS on which the stacked body LM is formed, and covered with the insulating layer 40. In the insulating layer 40, contacts, vias, wiring, and the like are formed to draw the peripheral circuit CBA to the surface of the insulating layer 40, and are connected to electrode pads, and the like formed on the upper surface of the insulating layer 40.

Subsequently, the support substrate SS and the semiconductor substrate SB are bonded to each other with the respective insulating layers 50 and 40, and the electrode pads in the insulating layers 50 and 40 are connected. Thereafter, the support substrate SS is removed by polishing to expose the source line SL, and the electrode film EL is connected via the insulating layer 60 in which the plug PG is formed.

Through the above process, the semiconductor memory device 1 of the first embodiment is manufactured.

### Comparative Example

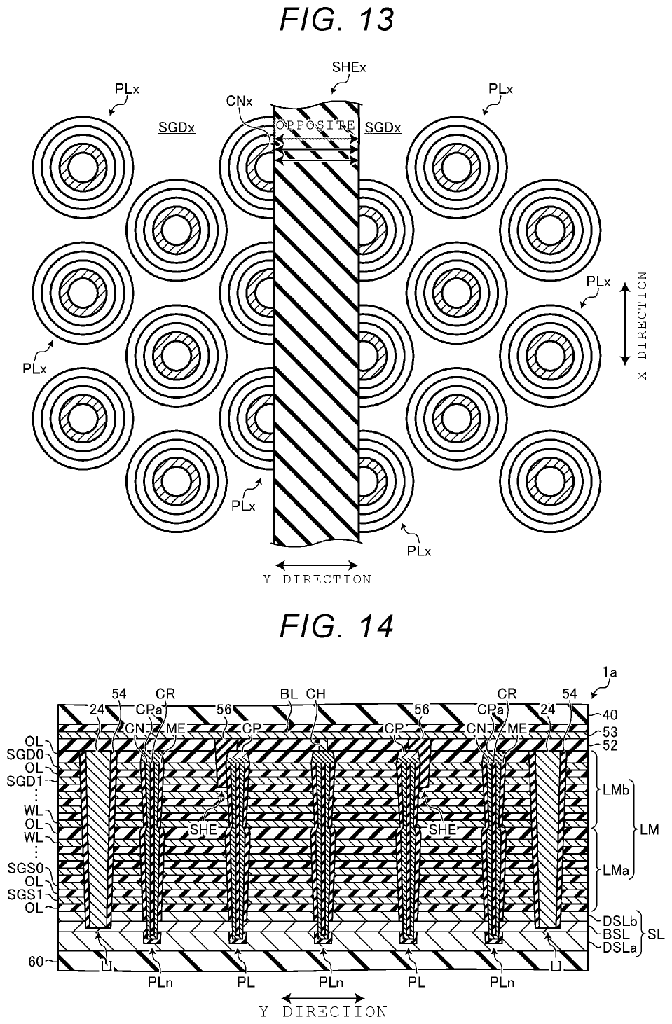

In a semiconductor memory device such as a three-dimensional nonvolatile memory, techniques are known in which one or more conductive layers including the uppermost conductive layer of a stacked body are divided into selection gate line patterns by a separation layer, and memory cells can be independently controlled for each section of the selection gate line. On the other hand, to increase memory capacity, pillars are arranged at high density in a periodic pattern in the memory region. Therefore, a separation layer may be formed at a position overlapping some of the pillars, resulting in missing of some portions of the pillars. FIG. 13 illustrates a pillar PLx of the comparative example in such state.

FIG. 13 is an XY cross-sectional view at a height position of a selection gate line SGDx of a semiconductor memory device according to the comparative example. As illustrated in FIG. 13, the pillars PLx of the comparative example are arranged at high density, for example, in a staggered pattern. Of the pillars PLx, a separation layer SHEx extending in the X direction is formed in a region between two rows of pillars PLx extending in the X direction while overlapping with pillars PLx on both sides in the Y direction. One end on one side in the Y direction of the pillar PLx that overlaps with the separation layer SHEx is missing due to the separation layer SHEx.

Here, in the pillar PLx where one side is missing due to the separation layer SHEx, a channel layer CNx in the missing portion will face the adjacent selection gate line SGDx through the separation layer SHEx, instead of the section of the selection gate line SGDx to which the pillar PLx belongs.

As a result, for the selection gate of the pillar PLx, the controllability by the selection gate line SGDx to which the pillar PLx belongs is partially impaired, and the influence of the electric field due to the selection gate line SGDx that the pillar PLx faces across the separation layer SHEx appears. Such phenomenon is also called neighbor interference.

Due to the above-mentioned neighbor interference, in the pillar PLx where one side is missing, a threshold voltage of the selection gate may decrease, or off-leakage may occur where current flows even though the selection gate is off.

Data in the memory cell is erased by flowing a large current via the channel layer CNx. However, when one side of the pillar PLx is missing due to the separation layer SHEx, the cross-sectional area of the channel layer CNx in the XY plane of the missing portion is reduced. Therefore, in the pillar PLx missing one side, the erase characteristics of the memory cell may deteriorate.

According to the semiconductor memory device 1 of the first embodiment, the separation layer SHE extends from above the stacked body LM into the stacked body LM at a position where at least a portion of the separation layer SHE overlaps with the pillar PL in the stacking direction of the stacked body LM, and a lower end is provided on the upper surface of the pillar PL at a position overlapping with the pillar PL.

Thereby, the structure of the pillar PL is maintained without missing even in the portion overlapping with the separation layer SHE. Therefore, a decrease in a threshold value and off-leakage of the selection gate line SGD in the pillar PL can be reduced. In addition, deterioration of the erase characteristics of the memory cell MC in the pillar PL can be reduced. As such, the functions of the memory cells MC and the like in the pillar PL can be maintained and the characteristics of the memory cells MC and the like can be improved.

By adopting a configuration that allows interference between the pillars PL and the separation layer SHE, the pillars PL can be arranged at high density while maintaining a periodic arrangement such as staggered pattern, and the storage capacity of the semiconductor memory device 1 can be increased. By maintaining the periodic arrangement of the pillars PL, it is also possible to reduce variations in the shape of the memory holes MH and dimensional conversion differences when forming the memory holes MH.

According to the semiconductor memory device 1 of the first embodiment, the cap layer CP of the pillar PL includes the cap layer CPb containing a dopant at the upper end of the pillar PL. As such, by implanting a dopant into the semiconductor layer, at least a portion of the cap layer CP at the upper end of the pillar PL acquires etching resistance. Thereby, when forming the groove GR that will later become the separation layer SHE, the cap layer CPb functions as a stopper layer, and the pillar PL is prevented from being eroded in the depth direction by the groove GR.

According to the semiconductor memory device 1 of the first embodiment, the plug CH is connected to the cap layer CPb and electrically connects the pillar PL and the bit line BL disposed above the pillar PL. When forming the separation layer SHE, by using the cap layer CPb, which has acquired etching resistance by dopant implantation, as a stopper layer, the cap layer CPb can function as a connection end with the plug CH.

### Modification

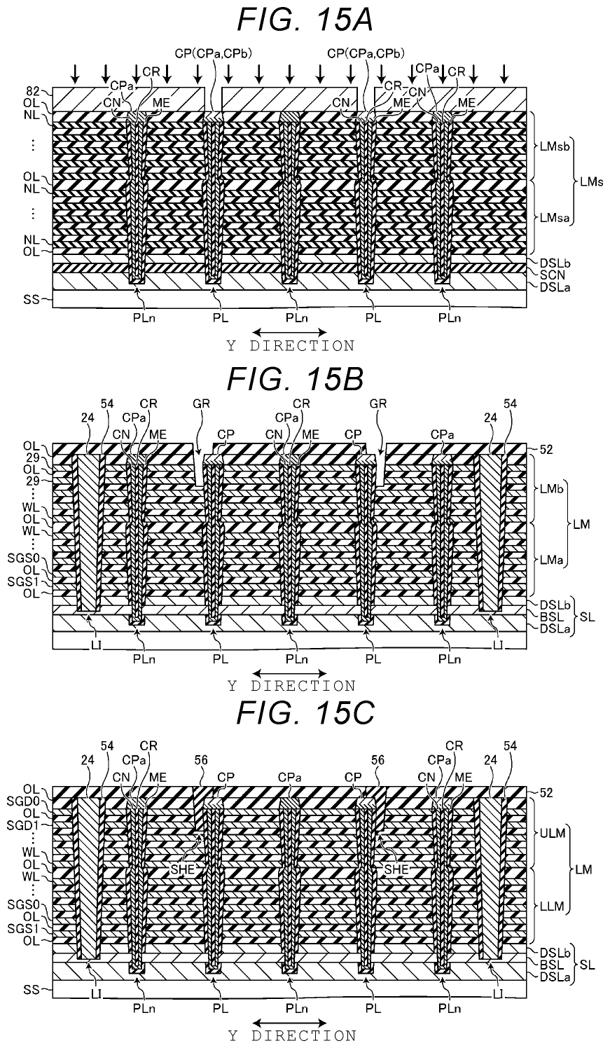

Next, a semiconductor memory device 1a according to a modification of the first embodiment will be described using FIGS. 14 to 15C. The semiconductor memory device 1a of the modification differs from the above-described first embodiment in that only the pillar PL disposed at a position overlapping with the separation layer SHE has the cap layer CPb.

In the following drawings, the same configurations as those in the first embodiment described above are denoted by the same reference the numerals, and description thereof may be omitted.

FIG. 14 is a cross-sectional view along the Y direction illustrating an example of the configuration of the semiconductor memory device 1a according to the modification of the first embodiment.

The semiconductor memory device 1a of the modification has a schematic configuration similar to that of the semiconductor memory device 1 of the first embodiment illustrated in FIG. 1 described above. The semiconductor memory device 1a has the same configuration as the semiconductor memory device 1 of the first embodiment illustrated in FIGS. 3A to 3B described above in the staircase region. That is, in the staircase region of the semiconductor memory device 1a, a plurality of columnar portions HR are distributed and arranged, similar to the first embodiment described above.

As illustrated in FIG. 14, a plurality of pillars PL and PLn are distributed and arranged in the memory region of the semiconductor memory device 1a. The pillar PL includes the cap layer CP including the cap layers CPa and CPb, and is disposed at a position overlapping the separation layer SHE in the stacking direction, as in the first embodiment described above.

The pillar PLn does not include the dopant-containing cap layer CPb at the upper end thereof, and is disposed at a position that does not overlap with the separation layer SHE in the memory region. More specifically, similar to the pillar PL, the pillar PLn includes the memory layer ME, the channel layer CN, and the core layer CR from the outer peripheral side, and instead of the cap layer CP including the cap layers CPa and CPb, includes the cap layer CPa, which is a semiconductor layer that entirely does not contain a dopant. As such, the pillar PLn has the same configuration as the pillar PL except for the cap layer CPb.

FIGS. 15A to 15C are cross-sectional views along the Y direction illustrating a part of the procedure of a manufacturing method of the semiconductor memory device 1a according to the modification of the first embodiment.

FIG. 15A illustrates how a dopant is implanted into a part of the cap layer CPa, and corresponds to the process illustrated in FIG. 9B of the first embodiment described above. As illustrated in FIG. 15A, when implanting dopants, a resist pattern 82 is formed in advance on the upper surface of the stacked body LMs.

From the resist pattern 82, at least the upper end of the pillar PL, which is in the process of being formed and is located at a position overlapping with the separation layer SHE, is exposed, for example. The cap layer CPa that does not contain a dopant is already formed on the pillar PL that is currently being formed.

At least one of a dopant such as carbon and a P-type dopant such as boron, gallium, and indium is implanted via the resist pattern 82. As a result, a dopant is implanted into the surface layer portion of the cap layer CPa of the pillar PL that is being formed, which is exposed from the resist pattern 82, so that the hardened cap layer CPb is formed, or the cap layer CPb containing carriers at a high density is formed.

In the portions other than the above, no dopant is implanted into the pillars PL that are being formed and are covered with the resist pattern 82, and such portions become the pillars PLn including only the cap layer CPa.

Note that from the resist pattern 82 described above, a slightly wider range than the upper surface of the pillar PL which is being formed and which will overlap with the separation layer SHE may be exposed. Thereby, the dopant can be more reliably implanted into the entire surface of the target cap layer CPa.

FIG. 15B shows how the groove GR, that will become the separation layer SHE, is formed in the upper layer portion of the stacked body LM after the replacement process, and corresponds to the state after the resist pattern 81 is removed after the process of FIG. 12B of the above-described first embodiment.

As illustrated in FIG. 15B, after the replacement process, the insulating layer 52 is formed on the upper surface of the stacked body LM, and the upper surfaces of the pillars PL and PLn are covered with the insulating layer 52. The groove GR is formed to penetrate the insulating layer 52 and reach a predetermined depth in the stacked body LM.

Here, the pillar PL including the cap layer CPb is disposed at the position where the groove GR is formed. Therefore, the groove GR is formed using the cap layer CPb as a stopper layer, and the erosion of the pillar PL in the depth direction is prevented.

As illustrated in FIG. 15C, as in the first embodiment described above, the separation layer SHE is formed by filling the groove GR with the insulating layer 56.

Thereafter, the same process as in the first embodiment described above is performed, and the semiconductor memory device 1a according to the modification is manufactured.

According to the semiconductor memory device 1a of the modification, the same effects as those of the semiconductor memory device 1 of the first embodiment described above are achieved.

### Second Embodiment

Hereinafter, the second embodiment will be described with reference to the drawings, in detail. The second embodiment differs from the first embodiment described above in that the separation layer SHE is formed using a layer different from the cap layer CPb as a stopper layer.

In the following drawings, the same configurations as those in the first embodiment described above are denoted by the same reference numerals, and the description thereof may be omitted.

### Configuration Example of Semiconductor Memory Device

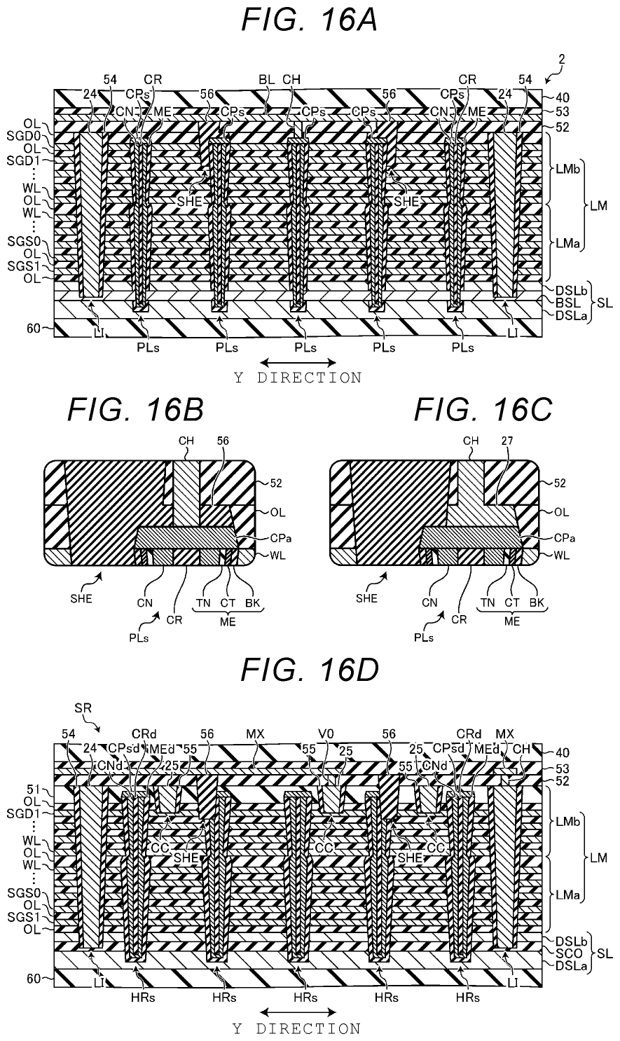

First, a detailed configuration example of a semiconductor memory device 2 of the second embodiment will be described with reference to FIGS. 16A to 16D. FIGS. 16A to 16D are diagrams illustrating one example of the configuration of the semiconductor memory device 2 according to the second embodiment.

More specifically, FIG. 16A is a cross-sectional view along the Y direction of the semiconductor memory device 2 including the memory region. FIGS. 16B and 16C are enlarged cross-sectional views of the upper end of a pillar PLs. FIG. 16D is a cross-sectional view along the Y direction of the semiconductor memory device 2 including the staircase region. Note that the structures below the insulating layer 60 and above the insulating layer 40 are omitted in FIGS. 16A and 16D.

The semiconductor memory device 2 of the second embodiment also has a schematic configuration similar to that of the semiconductor memory device 1 of the first embodiment illustrated in FIG. 1 described above.

As illustrated in FIG. 16A, a plurality of pillars PLs are distributed and arranged in the memory region of the semiconductor memory device 2. The plurality of pillars PLs do not have the dopant-containing cap layer CPb at the upper end, similar to the pillar PLn of the modification of the first embodiment described above, and a cap layer CPs, which is a semiconductor layer or the like that does not contain a dopant, is disposed on the upper end of the pillar PLS.

However, unlike the cap layer CPa of the pillar PLn described above, the cap layer CPs is a thin layer buried in the uppermost insulating layer OL of the stacked body LM. The plug CH extending through the insulating layers 52 and OL is connected to the upper surface of the cap layer CPs. Thereby, the pillar PLs and the bit line BL in the upper layer are electrically connected.

As in the first embodiment described above, some of the pillars PLs are disposed at positions overlapping with the separation layer SHE in the stacking direction. In the portion where the separation layer SHE and the pillar PLs overlap, the lower end of the separation layer SHE is located on the upper surface of the cap layer CPs at the upper end of the pillar PLS. That is, in the portion overlapping with the pillar PLs, the separation layer SHE does not extend below the upper surface of the cap layer CPs within the stacked body LM.

In the formation process of the separation layer SHE, which will be described later, the shapes of the separation layer SHE on the upper surface of the cap layer CPs and the plug CH connected to the cap layer CPs may vary depending on the filling performance of the insulating layer 56 configuring the separation layer SHE. FIGS. 16B and 16C respectively illustrate different configuration examples of the upper surface of the cap layer CPs.

In the example illustrated in FIGS. 16A and 16B, the lower end of the separation layer SHE extends along the upper surface of the cap layer CPs from a position overlapping with the pillar PLs in the stacking direction. As a result, at least a portion of the upper surface of the cap layer CPs is covered with the insulating layer 56 that configures the separation layer SHE.

In the above case, the plug CH penetrates the insulating layers 52 and OL, and the insulating layer 56 of the separation layer SHE covering the upper surface of the cap layer CPs to be connected to the cap layer CPs.

In the example shown in FIG. 16C, the lower end of the separation layer SHE remains on the upper surface of the cap layer CPs at a position overlapping the pillar PLs in the stacking direction. On the other hand, a conductive layer 27 such as a tungsten layer configuring the plug CH extends from the connection portion with the cap layer CPs to the periphery along the upper surface of the cap layer CPs. As a result, at least a portion of the upper surface of the cap layer CPs is covered with the conductive layer 27 that configures the plug CH.

As illustrated in FIG. 16D, a plurality of columnar portions HRs are distributed and arranged in the staircase region of the semiconductor memory device 2. Similar to the columnar portion HR of the first embodiment described above, the plurality of columnar portions HRs do not have a configuration corresponding to the cap layer CPb of the pillar PL at the upper end, and a thin dummy layer CPsd which is a semiconductor layer or the like corresponding to the cap layer CPs of the pillar PLS described above is disposed on the upper ends of the columnar portions HRs. However, the columnar portion HRs may not have a configuration corresponding to the cap layer CPs at the upper end.

As in the first embodiment described above, some of the columnar portions HRs are disposed at positions overlapping with the separation layer SHE in the stacking direction. In the portion where the separation layer SHE and the columnar portion HRs overlap, the lower end of the separation layer SHE erodes the columnar portion HRs and extends in the depth direction of the columnar portion HRs. As a result, some of the columnar portions HRs are missing.

### Method of Manufacturing Semiconductor Memory Device

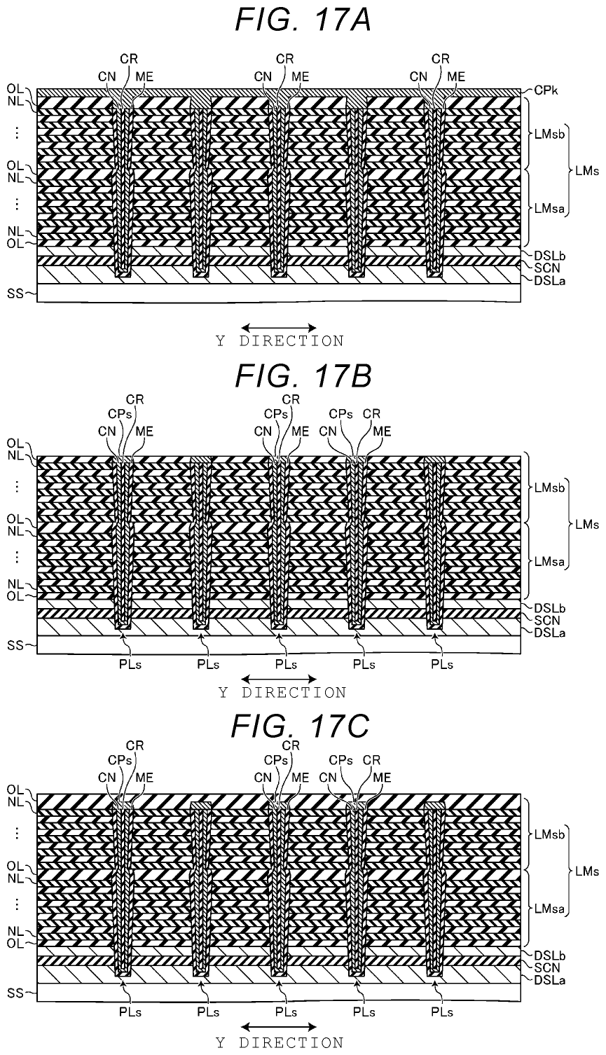

Next, a method for manufacturing the semiconductor memory device 2 of the second embodiment will be described with reference to FIGS. 17A to 21C. FIGS. 17A to 21C are diagrams sequentially illustrating a part of the procedure of the manufacturing method of the semiconductor memory device 2 according to the second embodiment.

FIG. 17A illustrates how the semiconductor layer CPk is formed in a region including the depression DN provided by etch-back, and corresponds to the process illustrated in FIG. 8C of the first embodiment described above.

As illustrated in FIG. 17B, the semiconductor layer CPk on the upper surface of the stacked body LMs is removed by CMP or the like, and a part of the uppermost insulating layer OL of the stacked body LMs is further removed in the layer thickness direction. As a result, the semiconductor layer CPk formed in the uppermost insulating layer OL becomes thinner together with the uppermost insulating layer OL, and the pillar PLS including the thin cap layer CPs at the upper end is formed.

As illustrated in FIG. 17C, the thinned uppermost insulating layer OL is stacked. As a result, the cap layer CPs at the upper end of the pillar PLs is buried in the uppermost insulating layer OL.

Although not illustrated, the same process as in FIGS. 17A to 17C described above may be performed in parallel in a region that will later become the staircase region, thereby forming the columnar portion HRS including the dummy layer CPsd corresponding to the cap layer CPs of the pillar PLs.

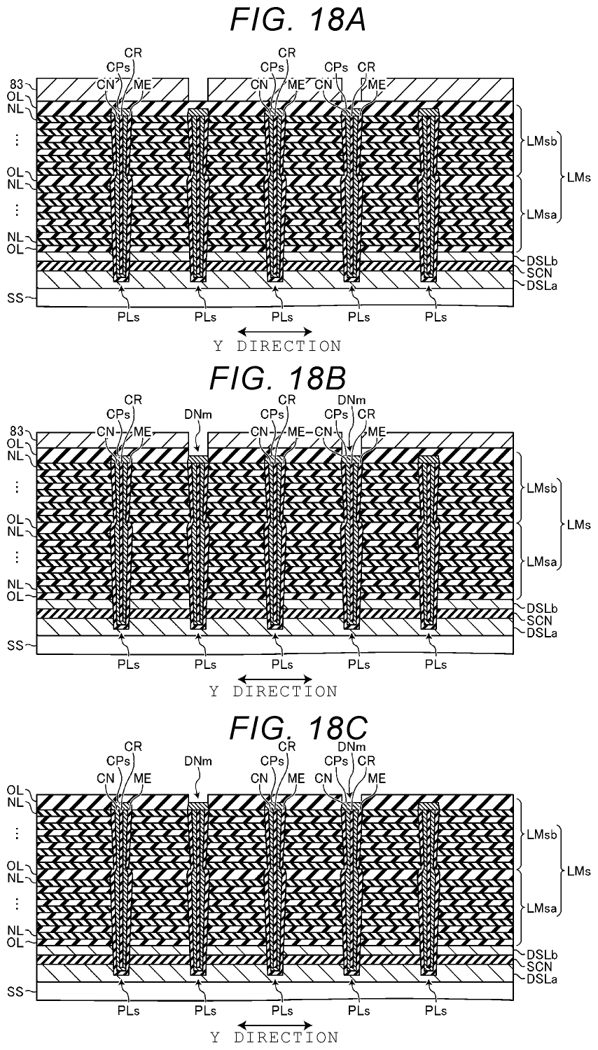

As illustrated in FIG. 18A, a resist pattern 83 is formed on the upper surface of the stacked body LMs. From the resist pattern 83, at least the insulating layer OL above the pillar PLs, which is disposed at a position that will overlap with the separation layer SHE, is exposed.

As illustrated in FIG. 18B, using the resist pattern 83 as a mask, the insulating layer OL exposed from the resist pattern 83 is removed by etching to form a depression DNm in the insulating layer OL. As a result, at least the upper surface of the pillar PLs that will overlap with the separation layer SHE is exposed from the bottom surface of the depression DNm formed in the insulating layer OL.

As illustrated in FIG. 18C, the resist pattern 83 is removed by, for example, ashing using oxygen plasma.

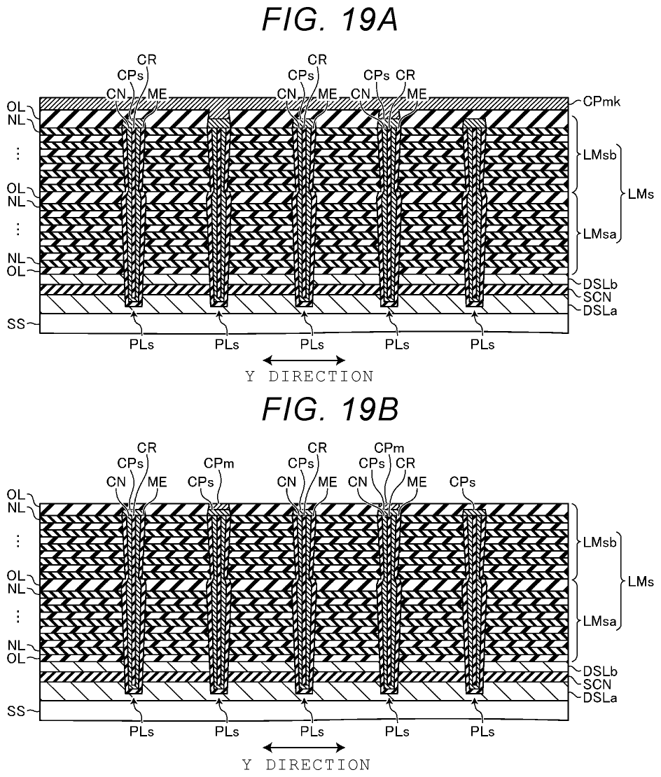

As illustrated in FIG. 19A, a boron-containing layer CPmk is formed on the upper surface of the stacked body LMs including the depression DNm above the pillar PLS. The boron-containing layer CPmk is formed, for example, by a CVD method using a boron-containing gas.

As the boron-containing gas, for example, diborane (B₂H₆) gas or boron trichloride (BCl₃) may be used. By thermally decomposing such boron-containing gas on the stacked body LMs by a CVD method or the like, the boron-containing layer CPmk containing boron as a main component is formed. The boron-containing layer CPmk functions, for example, as an inorganic hard mask layer.

As illustrated in FIG. 19B, the boron-containing layer CPmk on the upper surface of the stacked body LMs is removed by CMP or the like, and a hard mask layer CPm as a first layer made of the boron-containing layer is formed at the upper end of the pillar PLs.

Note that in the process illustrated in FIG. 18A, the resist pattern 83 described above may be formed so that a slightly wider range than the upper surface of the pillar PLs that will overlap with the separation layer SHE is exposed. Thereby, the hard mask layer CPm can be formed to more reliably cover the entire upper surface of the cap layer CPs of the pillar PLS.

Although not illustrated, the processes illustrated in FIGS. 18A to 19B described above are not performed in a region that will later become a staircase region. Therefore, the hard mask layer CPm is not formed on the upper surface of any columnar portion HRs. Here, during the processing shown in FIGS. 18A to 19B described above, the region that will later become the staircase region can be covered and protected with a photoresist layer or the like.

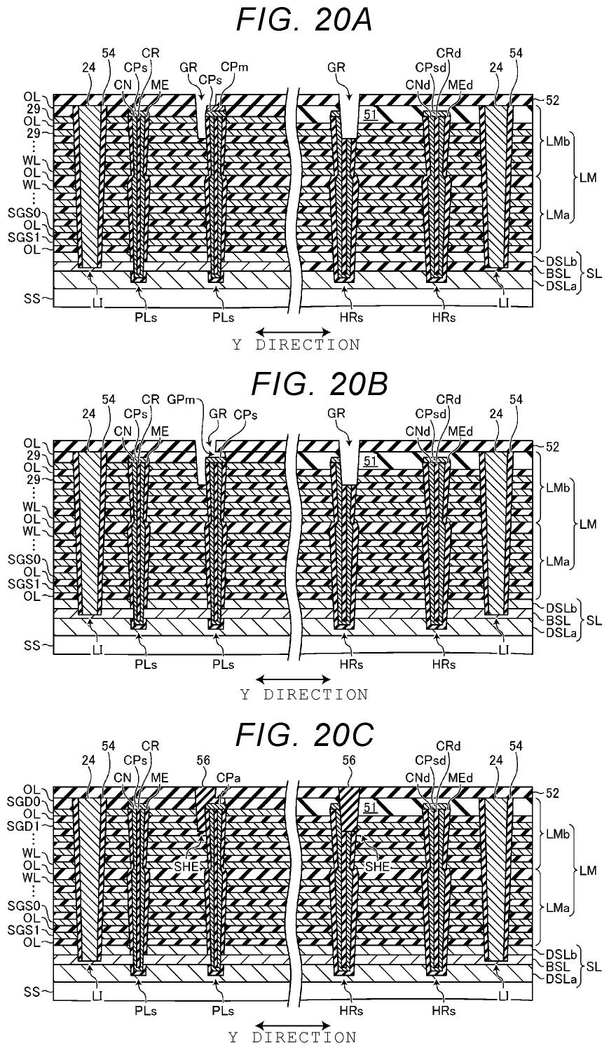

FIG. 20A illustrates the state where the groove GR, that will become the separation layer SHE, is formed in the upper layer portion of the stacked body LM after the replacement process, and corresponds to the state where the resist pattern 81 is removed after the process of FIG. 12B of the above-described first embodiment.

As illustrated in FIG. 20A, after the replacement process, the insulating layer 52 is formed on the upper surface of the stacked body LM, and the upper surface of the pillar PLs is covered with the insulating layer 52. The groove GR is formed to penetrate the insulating layer 52 and reach a predetermined depth in the stacked body LM.

At this time, the hard mask layer CPm is formed on the cap layer CPs of the pillar PLs at the position where the groove GR is formed. Therefore, the groove GR is formed using the hard mask layer CPm as a stopper layer, and the erosion of the pillar PLs in the depth direction is prevented.

On the other hand, the hard mask layer CPm is not formed on the dummy layer CPsd of the columnar portion HRS. Therefore, at the position overlapping with the columnar portion HRS, the groove GR extends in the stacking direction within the columnar portion HRs while eroding the columnar portion HRs in the depth direction. As a result, a partial configuration of the columnar portion HRs that overlaps with the groove GR is missing.

As illustrated in FIG. 20B, the hard mask layer CPm formed at the upper end of some of the pillars PLs and exposed in the groove GR is removed by wet etching or the like. As a result, a gap GPm from which the hard mask layer CPm is removed is generated between the upper surface of the pillar PLs and the uppermost insulating layer OL of the stacked body LM that covers the upper surface of the pillar PLS.

As illustrated in FIG. 20C, the groove GR is filled with the insulating layer 56 to form the separation layer SHE. Here, when the filling performance of the insulating layer 56 is sufficiently high, the gap GPm generated on the upper surface of the pillar PLs is almost completely filled with the insulating layer 56.

Thereby, as illustrated in FIG. 16B described above, a shape is obtained in which the insulating layer 56 at the lower end of the separation layer SHE covers at least a portion of the upper surface of the cap layer CPs of the pillar PLs.

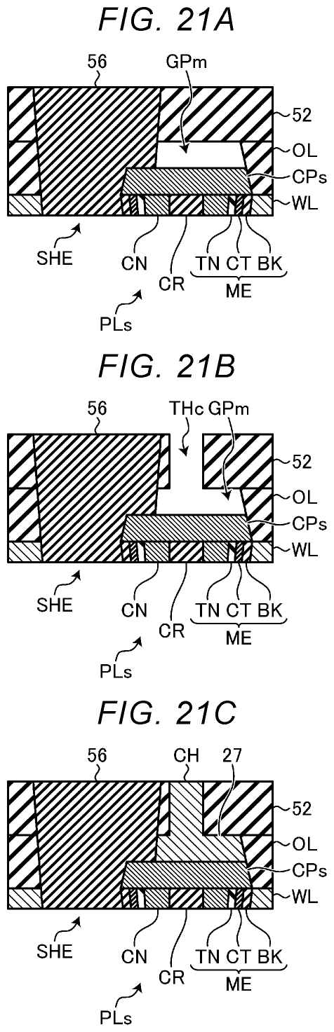

On the other hand, when the filling performance of the insulating layer 56 is insufficient, there is a possibility that the gap GPm on the upper surface of the pillar PLs will not be completely filled. An example of such case is illustrated in FIGS. 21A to 21C. FIGS. 21A to 21C are enlarged cross-sectional views of the upper end of the pillar PLs illustrating how the plug CH is formed.

As illustrated in FIG. 21A, even after filling the groove GR with the insulating layer 56 to form the separation layer SHE, a part of the gap GPm or the entire gap GPm on the upper surface of the pillar PLs shall remain without being filled by the insulating layer 56.

As illustrated in FIG. 21B, to form the plug CH connected to the cap layer CPs on the upper surface of the pillar PLs, a through hole THc penetrating the insulating layer 52 and the like is formed. The through hole THc penetrating the insulating layer 52 is in communication with the gap GPm on the upper surface of the pillar PLS.

As illustrated in FIG. 21C, the conductive layer 27 such as a tungsten layer is filled into the through hole THc to form the plug CH. Here, the conductive layer 27 is also filled into the gap GPm on the upper surface of the pillar PLs via the through hole THC. Thereby, as illustrated in FIG. 16C described above, a shape is obtained in which the conductive layer 27 at the lower end of the plug CH covers at least a part of the upper surface of the cap layer CPs of the pillar PLs. Thereby, the lower end of the plug CH is connected to the cap layer CPs by the conductive layer 27 filled in the gap GPm.

In this manner, depending on the difference in the filling performance of the insulating layer 56 configuring the separation layer SHE, the material filled in the gap GPm generated on the upper surface of the pillar PLs may be different, such as the insulating layer 56 or the conductive layer 27.

However, the above-described FIGS. 16B and 20C illustrate an example in which the gap GPm is almost completely filled with the insulating layer 56, and the above-described FIGS. 16C and 21A to 21C illustrate an example in which the gap GPm is hardly filled with the insulating layer 56. However, the examples are extreme cases. Regardless of the above examples, the inside of the gap GPm may be filled with the insulating layer 56 and the conductive layer 27 having a predetermined volume ratio.

According to the manufacturing method of the semiconductor memory device 2 of the second embodiment, the pillar PLs in which the hard mask layer CPm is formed on the upper surface of the cap layer CPs by the CVD method using a boron-containing gas is formed. Such hard mask layer CPm can also prevent the lower end of the groove GR from eroding the pillar PLs and extending in the depth direction.

According to the manufacturing method of the semiconductor memory device 2 of the second embodiment, a configuration is obtained in which the lower end of the separation layer SHE extends along the upper surface of the cap layer CPs from a position overlapping with the pillar PLs in the stacking direction, and covers at least part of the upper surface of the pillar PLS. Alternatively, a configuration is obtained in which the lower end of the plug CH extends from the connection portion of the pillar PLs with the cap layer CPs to the periphery along the upper surface of the cap layer CPs, and covers at least a part of the upper surface of the pillar PLs.

According to the semiconductor memory device 2 of the second embodiment, other effects similar to those of the semiconductor memory device 1 of the above-described first embodiment are achieved.

### Modification

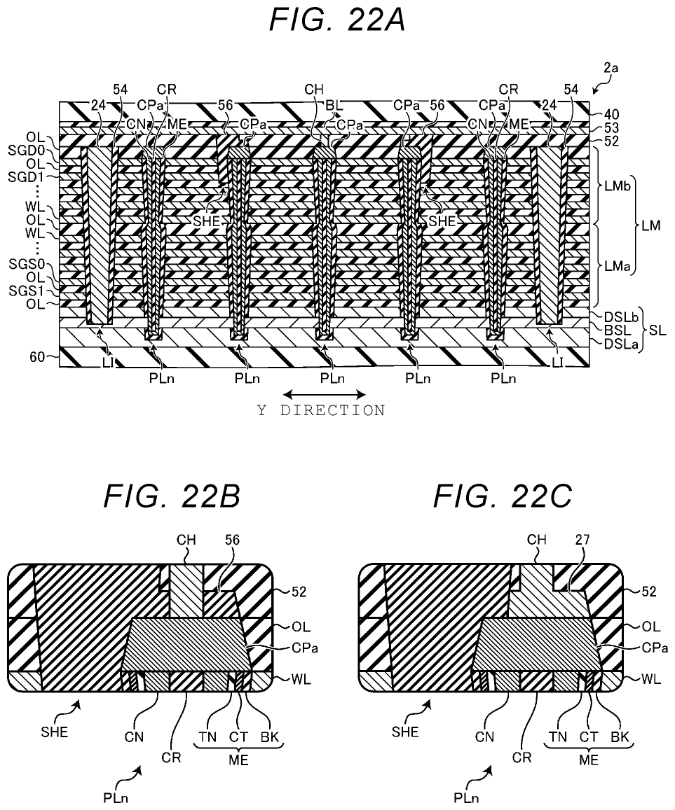

Next, a semiconductor memory device 2a of a modification of the second embodiment will be described with reference to FIGS. 22A to 25C. The semiconductor memory device 2a of the modification differs from the above-described second embodiment in that a CVD-carbon layer is used as a hard mask layer at the upper end of the pillar.

In the following drawings, the same configurations as those in the second embodiment described above are denoted by the same reference numerals, and the description thereof may be omitted.

FIGS. 22A to 22C are cross-sectional views along the Y direction illustrating an example of the configuration of the semiconductor memory device 2a according to the modification of the second embodiment.

More specifically, FIG. 22A is a cross-sectional view along the Y direction of the semiconductor memory device 2a including the memory region. In FIG. 22A, the structure below the insulating layer 60 and above the insulating layer 40 is omitted. FIGS. 22B and 22C are enlarged cross-sectional views of the upper end of the pillar PLn.

The semiconductor memory device 2a of the modification has a schematic configuration almost similar to that of the semiconductor memory device 1 of the first embodiment illustrated in FIG. 1 described above. The semiconductor memory device 2a has the same configuration as the semiconductor memory device 1 of the first embodiment illustrated in FIGS. 3A to 3B described above in the staircase region. That is, in the staircase region of the semiconductor memory device 2a, a plurality of columnar portions HR are distributed and arranged, similar to the first embodiment described above.

As illustrated in FIGS. 22A to 22C, a plurality of pillars PLn are distributed and arranged in the memory region of the semiconductor memory device 2a. The plurality of pillars PLn have the same configuration as the pillar PLn of the modification of the first embodiment described above.

That is, the pillar PLn does not include the dopant-containing cap layer CPb at the upper end, and the pillar includes the cap layer CPa, which is a semiconductor layer that entirely does not contain dopants. The upper end of the cap layer CPa is located on the upper surface of the uppermost insulating layer OL of the stacked body LM. The plug CH penetrating and extending through the insulating layer 52 is connected to the upper surface of the cap layer CPa. Thereby, the pillar PLa and the bit line BL in the upper layer are electrically connected.

As in the first and second embodiments described above, some of the pillars PLn are disposed at positions overlapping with the separation layer SHE in the stacking direction. In the portion where the separation layer SHE and the pillar PLn overlap, the lower end of the separation layer SHE is located on the upper surface of the cap layer CPa at the upper end of the pillar PLn. That is, in the portion overlapping with the pillar PLa, the separation layer SHE does not extend below the upper surface of the cap layer CPa within the stacked body LM.

The shapes of the separation layer SHE on the upper surface of the cap layer CPa and the plug CH connected to the cap layer CPa may vary depending on the difference in the filling performance of the insulating layer 56 configuring the separation layer SHE. FIGS. 22B and 22C respectively illustrate an example in which the upper surface of the cap layer CPa has a different configuration.

In the example illustrated in FIGS. 22A and 22B, the lower end of the separation layer SHE extends along the upper surface of the cap layer CPa from a position overlapping with the pillar PLn in the stacking direction. As a result, at least a portion of the upper surface of the cap layer CPa is covered with the insulating layer 56 that configures the separation layer SHE.

In this case, the plug CH penetrates the insulating layer 52 and the insulating layer 56 of the separation layer SHE covering the upper surface of the cap layer CPa to be connected to the cap layer CPa.

In the example shown in FIG. 22C, the lower end of the separation layer SHE remains on the upper surface of the cap layer CPa at a position overlapping the pillar PLn in the stacking direction. On the other hand, the conductive layer 27 such as a tungsten layer configuring the plug CH extends from the connection portion with the cap layer CPa to the periphery along the upper surface of the cap layer CPa. As a result, at least a portion of the upper surface of the cap layer CPa is covered with the conductive layer 27 that configures the plug CH.

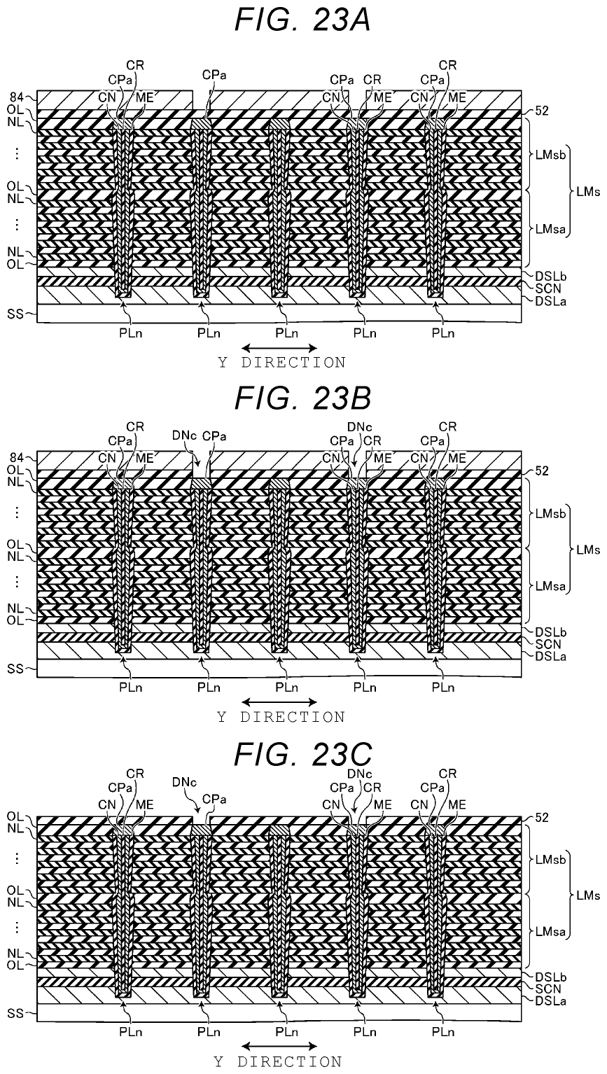

Next, a method for manufacturing the semiconductor memory device 2a of the modification will be described with reference to FIGS. 23A to 25C. FIGS. 23A to 25C are diagrams sequentially illustrating a part of the procedure of the manufacturing method of the semiconductor memory device 2a according to modification of the second embodiment. More specifically, FIGS. 23A to 25C are cross-sectional views along the Y direction including a memory region during manufacturing.

FIG. 23A illustrates how the pillars PLn are formed in the stacked body LMs before replacement, and corresponds to the process illustrated in FIG. 18A of the second embodiment described above.

As illustrated in FIG. 23A, without implanting a dopant into the cap layer CPa, after forming the pillar PLn similar to the modification of the above-described first embodiment in the stacked body LMs, the insulating layer 52 is formed to be thinner than the final layer thickness on the upper surface of the stacked body LMs. The thickness of the insulating layer 52 here is preferably approximately the same as, for example, the thickness of the hard mask layer formed in subsequent processing.

A resist pattern 84 is formed on the upper surface of the stacked body LMs. From the resist pattern 84, at least the insulating layer OL above the pillar PLn, which is disposed at a position that will overlap with the separation layer SHE, for example, is exposed. A slightly wider range than the upper surface of the pillar PLn, which will overlap with the separation layer SHE, may be exposed from the resist pattern 84 so that the upper surface of the cap layer CPa is covered by a hard mask layer of sufficient size in subsequent processing.

As illustrated in FIG. 23B, using the resist pattern 84 as a mask, the insulating layer OL exposed from the resist pattern 84 is removed by etching to form a depression DNc in the insulating layer OL. As a result, at least the upper surface of the pillar PLn that will overlap with the separation layer SHE is exposed from the bottom surface of the depression DNc formed in the insulating layer OL.

As illustrated in FIG. 23C, the resist pattern 84 is removed by, for example, ashing using oxygen plasma.

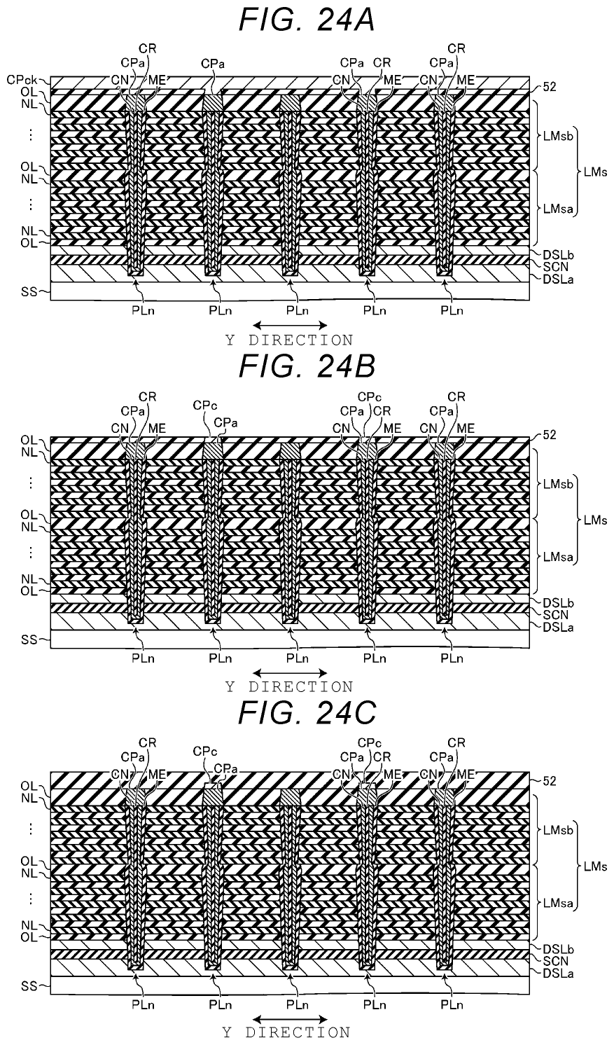

As illustrated in FIG. 24A, a CVD-carbon layer CPck is formed on the upper surface of the stacked body LMs including the depression DNc above the pillar PLn. As described above, the CVD-carbon layer CPck is an organic layer that is formed by, for example, a CVD method using a carbon-containing gas, and can be removed by ashing using oxygen plasma or the like.

As illustrated in FIG. 24B, the CVD-carbon layer CPck on the upper surface of the stacked body LMs is removed by CMP or the like, and a hard mask layer CPc as a first layer made of the CVD-carbon layer is formed on the upper end of the pillar PLn.

As illustrated in FIG. 24C, the insulating layer 52 is stacked, and the hard mask layer CPc formed on the upper surface of the pillar PLn is buried in the insulating layer 52.

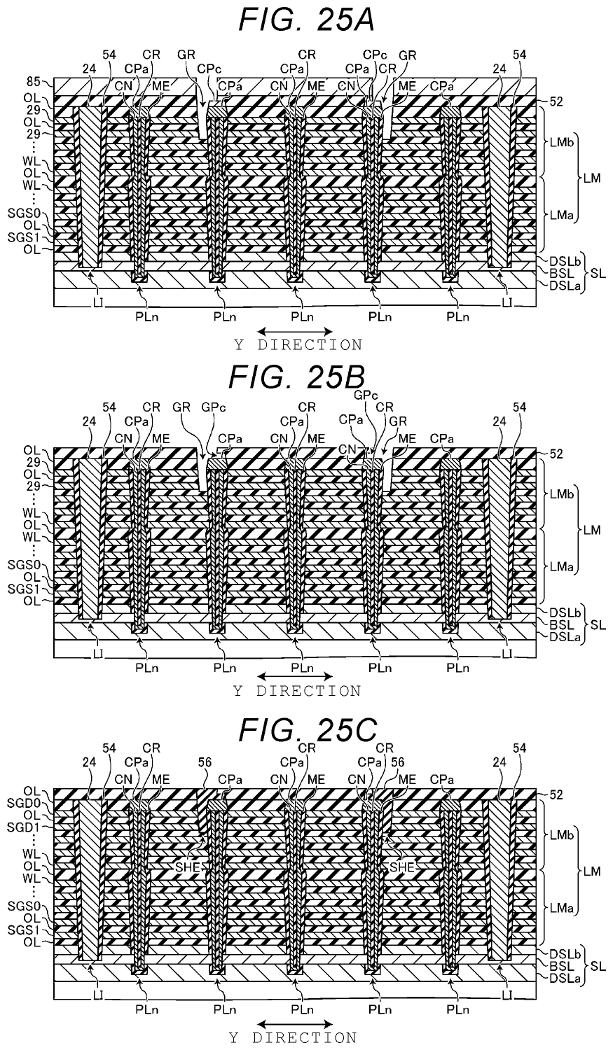

FIG. 25A illustrates the state where the groove GR, that will become the separation layer SHE, is formed in the upper layer portion of the stacked body LM after the replacement process, and corresponds to the process of FIG. 12B of the above-described first embodiment.

As illustrated in FIG. 25A, after the replacement process, the insulating layer 52 is formed on the upper surface of the stacked body LM, and the upper surface of the pillar PLn is covered with the insulating layer 52. The groove GR is formed to penetrate the insulating layer 52 and reach a predetermined depth in the stacked body LM.

Here, the hard mask layer CPc is formed on the cap layer CPa of the pillar PLn at the position where the groove GR is formed. Therefore, the groove GR is formed using the hard mask layer CPc as a stopper layer, and the erosion of the pillar PLn in the depth direction is prevented.

As illustrated in FIG. 25B, a resist pattern 85 is removed by, for example, ashing using oxygen plasma. Here, the hard mask layer CPc formed at the upper end of some of the pillars PLn and exposed in the groove GR is also removed by ashing. As a result, a gap GPc from which the hard mask layer CPc is removed is generated between the upper surface of the pillar PLn and the insulating layer 52 covering the upper surface of the pillar PLn.

As illustrated in FIG. 25C, the groove GR is filled with the insulating layer 56 to form the separation layer SHE. Here, when the filling performance of the insulating layer 56 is sufficiently high, the gap GPc generated on the upper surface of the pillar PLn is almost completely filled with the insulating layer 56. Thereby, as illustrated in FIG. 22B described above, a shape is obtained in which the insulating layer 56 at the lower end of the separation layer SHE covers at least a portion of the upper surface of the cap layer CPa of the pillar PLn.

On the other hand, when the filling performance of the insulating layer 56 is insufficient, the conductive layer 27 of the plug CH to be formed thereafter fills the gap GPc on the upper surface of the pillar PLn. Thereby, as illustrated in FIG. 22C, a shape is obtained in which the conductive layer 27 of the plug CH covers at least a part of the upper surface of the cap layer CPa of the pillar PLn.

Note that regardless of the examples in FIGS. 22B and 25C or the example in FIG. 22C, the gap GPc may be defined by the insulating layer 56 and the conductive layer 27 in a predetermined volume ratio, depending on the filling performance of the insulating layer 56.

According to the manufacturing method of the semiconductor memory device 2a of the modification, the pillar PLs in which the hard mask layer CPc is formed on the upper surface of the cap layer CPa by the CVD method using a carbon-containing gas is formed. Such hard mask layer CPc can also prevent the lower end of the groove GR from eroding the pillar PLn and extending in the depth direction.

According to the manufacturing method of the semiconductor memory device 2a of the modification, after forming the groove GR, the hard mask layer CPc is removed by ashing. As described above, by using the hard mask layer CPc such as a CVD-carbon layer, the hard mask layer CPc after use can be removed by a simpler method such as ashing.

According to the semiconductor memory device 2a of the modification, the other effects similar to those of the semiconductor memory device 2 of the second embodiment are achieved.

In the second embodiment and the modification described above, the manufacturing method is partially different between the second embodiment and the modification so that the height position of the upper ends of the pillars PLs and PLn themselves are aligned between the pillars PLs and PLn in which the hard mask layers CPm and CPc are formed and the pillars PLs and PLn in which the hard mask layers CPm and CPc are not formed.

However, the method of the modification may be applied when forming the hard mask layer CPm of the second embodiment, and the method of the second embodiment may be applied when forming the hard mask layer CPc of the modification. In this case, the height positions of the upper ends of the pillars PLs and PLn themselves are different between the pillars PLs and PLn in which the hard mask layers CPm and CPc are formed and the pillars PLs and PLn in which the hard mask layers CPm and CPC are not formed.

### Other Embodiments

In the first and second embodiments and the modifications described above, the staircase regions SR are disposed at both ends of the stacked body LM in the X direction. However, the staircase region may be disposed at the center portion of the stacked body when viewed from the stacking direction by digging the center portion of the stacked body in a staircase shape.

In the first and second embodiments and the modifications described above, the pillar PL and the like are connected to the source line SL on the side surface of the channel layer CN, but the present disclosure is not limited thereto. For example, the pillar may be configured such that the memory layer on the bottom surface of the pillar is removed and the lower end of the channel layer is connected to the source line.

In the first and second embodiments and the modifications described above, the stacked body LM has a 2-Tier structure including the two stacked bodies LMa and LMb. However, the number of tiers in the stacked body may be 1 Tier, or 3 Tiers or more. By increasing the number of Tiers as such, the number of layers such as word lines WL can be further increased.

In the first and second embodiments and the modification described above, the peripheral circuit CBA is disposed above the stacked body LM. However, the peripheral circuit may be disposed below the stacked body or on the same level as the stacked body.

When the peripheral circuit is disposed below the stacked body, the source line and the stacked body may be formed, for example, on an insulating layer of a semiconductor substrate including the peripheral circuit covered with an insulating layer. When the peripheral circuit is disposed on the same level as the stacked body, the stacked body may be formed at a different position from the peripheral circuit on the semiconductor substrate where the peripheral circuit is formed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body including a plurality of conductive layers and a plurality of insulating layers alternately stacked in a vertical direction;
a first pillar including a semiconductor layer extending within the stacked body in the vertical direction; and
a separation layer penetrating through an uppermost conductive layer among the conductive layers, or the uppermost conductive layer and an another one of the conductive layers that is coupled to the uppermost conductive layer in the vertical direction, extending within the stacked body in a first direction that intersects the vertical direction, and separating one or more conductive layers including the uppermost conductive layer in a second direction that intersects the vertical direction and the first direction, wherein
the separation layer
includes at least a portion extending into the stacked body that is overlapped with the first pillar in the vertical direction, and having a lower end in contact with an upper surface of the first pillar.

2. The semiconductor memory device according to claim 1, wherein
the semiconductor layer includes a dopant-containing layer having a dopant around an upper end of the first pillar.

3. The semiconductor memory device according to claim 2, wherein
the dopant includes at least one of carbon or a P-type dopant.

4. The semiconductor memory device according to claim 2, wherein
the dopant-containing layer includes at least one of boron, gallium, or indium.

5. The semiconductor memory device according to claim 1, wherein
the lower end of the separation layer
covers at least a portion of the upper surface of the first pillar.

6. The semiconductor memory device according to claim 5, further comprising:
a plug penetrating through the separation layer and electrically coupled to the first pillar and a bit line disposed above the first pillar.

7. The semiconductor memory device according to claim 1, further comprising:
a plug electrically coupled to the first pillar and a bit line disposed above the first pillar, wherein
the lower end of the plug extends from a connection portion of the first pillar with the semiconductor layer to a periphery along the upper surface of the semiconductor layer, and covers at least a portion of the upper surface of the first pillar.

8. A method for manufacturing a semiconductor memory device, the method comprising:
forming a stacked body including a plurality of conductive layers and a plurality of first insulating layers alternately stacked in a vertical direction;
forming a first pillar including a semiconductor layer extending within the stacked body, wherein a first layer of a material different from the semiconductor layer is formed on an upper surface of the semiconductor layer;
forming a separation layer that penetrates through an uppermost conductive layer of the stacked body, or the uppermost conductive layer and at least another one of the conductive layers that is in direct contact with the uppermost conductive layer in the vertical direction, extends within the stacked body in a first direction that intersects the vertical direction, and separates one or more of the conductive layers including the uppermost conductive layer in a second direction that intersects the vertical direction and the first direction; and
when forming the separation layer, forming a groove extending into the stacked body and extending in the first direction within the stacked body, with the first layer serving as a stopper layer, wherein the groove is located at a position at least partially overlapped with the first pillar in the vertical direction; and
filling the groove with a second insulating layer.

9. The method for manufacturing a semiconductor memory device according to claim 8, wherein
the first layer is formed by implanting a dopant into an upper end of the semiconductor layer.

10. The method for manufacturing a semiconductor memory device according to claim 8, wherein
the first layer is formed by chemical vapor deposition using boron-containing gas.

11. The method for manufacturing a semiconductor memory device according to claim 8, wherein
the first layer is formed by chemical vapor deposition using carbon-containing gas.

12. The method for manufacturing a semiconductor memory device according to claim 11, wherein
after forming the groove, the first layer is removed by ashing.

13. A semiconductor memory device comprising:
a stacked body including a plurality of conductive layers and a plurality of insulating layers alternately stacked in a vertical direction;
a first pillar including a semiconductor layer within the stacked body in the vertical direction; and
a separation layer extending within the stacked body in a first direction that intersects the vertical direction, separating one or more of the conductive layers in a second direction that intersects the vertical direction and the first direction, and including at least one portion extending into the stacked body that is overlapped with the first pillar in the vertical direction, wherein
the at least one portion of the separation layer has a lower end in contact with an upper surface of the first pillar.

14. The semiconductor memory device according to claim 13, wherein
the semiconductor layer includes a dopant-containing layer with a dopant around an upper end of the first pillar.

15. The semiconductor memory device according to claim 14, wherein
the dopant includes at least one of carbon or a P-type dopant.

16. The semiconductor memory device according to claim 14, wherein
the dopant-containing layer includes at least one of boron, gallium, or indium.
